(19) United States
(12) Patent Application Publication
(10) Pub. No.: US 2026/0239663 A1
(43) Pub. Date: Aug. 13, 2026

(54) SEMICONDUCTOR DEVICE AND METHOD FOR FORMING A DIELECTRIC STRUCTURE IN A TRENCH

(71) Applicant: Infineon Technologies Austria AG, Villach (AT)

(72) Inventors: Harsh Naik, El Segundo, CA (US); Robert Haase, San Pedro, CA (US); Sanja Radosavljevic, Villach (AT)

(21) Appl. No.: 19/535,365

(22) Filed: Feb. 10, 2026

(30) Foreign Application Priority Data
Feb. 11, 2025 (DE) 102025105013.9

(51) Int. Cl. H10D 30/66; H10D 30/01; H10D 64/00; H10D 12/00; H10D 12/01

(52) U.S. Cl. CPC H10D 30/665; H10D 30/0297; H10D 30/668; H10D 64/112; H10D 64/117; H10D 12/038; H10D 12/415; H10D 12/481

(57) ABSTRACT

In an embodiment, a semiconductor device includes: a semiconductor substrate having a first major surface; at least one trench formed in the first major surface of the semiconductor substrate, the at least one trench having a base and a side wall extending from the base to the first major surface; and a field plate located in the trench and electrically insulated from the semiconductor substrate by a dielectric structure. The dielectric structure includes a bottom dielectric extending between the base of the trench and a lower surface of the field plate. The bottom dielectric includes a slightly doped polysilicon member.

### BACKGROUND

Transistors used in power electronic applications may be fabricated with silicon (Si) semiconductor materials. Common transistor devices for power applications include Si CoolMOS^{TM}, Si Power MOSFETs, and Si Insulated Gate Bipolar Transistors (IGBTs).

Some electrically conducting structures integrated into semiconductor devices are electrically insulated from other parts of the device to ensure reliable functioning of the semiconductor device. Examples of such conducting structures are gate electrodes and field plates, also known as field electrodes, which are insulated from the semiconductor substrate by insulation layers such as oxide layers. For example, an electrically conductive field plate may be located in a trench formed in the semiconductor substrate. The field plate is electrically insulated from the semiconductor substrate by an insulating layer, also known as a field dielectric, that lines the trench.

A transistor device for power applications may be based on the charge compensation principle and may include an active cell field including a plurality of elongate trenches, each including a field plate for charge compensation. The trenches and the mesas that are formed between adjacent trenches each have an elongate striped structure.

It is desirable to further improve the performance and reliability of semiconductor devices, for example by further reducing the risk of undesirable electrical breakdown. Methods for fabricating a semiconductor device with good performance are also desirable.

### SUMMARY

In an embodiment, a semiconductor device is provided which comprises a semiconductor substrate comprising a first major surface, at least one trench formed in the first major surface of the semiconductor substrate, at least one trench having a base and a side wall extending from the base to the first major surface, a field plate and a dielectric structure located in the trench. The field plate is electrically insulated from the semiconductor substrate by the dielectric structure. The dielectric structure comprises a bottom dielectric extending between the base of the trench and a lower surface of the field plate and the bottom dielectric comprises a slightly doped polysilicon member.

In an embodiment, a semiconductor device is provided which comprises a semiconductor substrate comprising a first major surface, at least one trench formed in the first major surface of the semiconductor substrate, the at least one trench having a base and a side wall extending from the base to the first major surface, a field plate and a gate electrode located in the trench, the gate electrode being arranged above the field plate, and a dielectric structure located in the trench. The field plate and the gate electrode are electrically insulated from one another and the semiconductor substrate by the dielectric structure. An outer surface of the field plate comprises a height between an upper surface and an opposing lower surface and an outer surface that extends between the upper surface and the lower surface. At least one step is located in the outer surface intermediate the height of the field plate. The dielectric structure comprises a bottom dielectric extending between the base of the trench and a lower surface of the field plate and a dielectric layer arranged on the side wall of the trench. The bottom dielectric has a first thickness that is measured in a first direction that is orthogonal to the base of the trench and the dielectric layer on the side wall has a second thickness that is measured in a second direction that is orthogonal to the side wall of the trench and that is located at a position laterally adjacent a side face of the field plate; wherein the first thickness t1 is greater than the second thickness t2.

In an embodiment, a method for forming a dielectric structure in a trench is provided. The method comprises forming a trench in a first major surface of a semiconductor substrate, the trench comprising a base and a side wall that extends from the base to the first major surface, forming a first dielectric layer on the side wall and base of the trench, forming a bottom dielectric on the first dielectric on the base of the trench, the bottom dielectric comprising slightly doped polysilicon, forming a first intermediate dielectric layer on the slightly doped polysilicon, forming a field plate on the first intermediate dielectric layer, forming a second intermediate dielectric layer on the field plate and forming a gate electrode on the second intermediate dielectric layer.

In an embodiment, a method for forming a dielectric structure in a trench is provided. The method comprises forming a trench in a first major surface of a semiconductor substrate, the trench comprising a base and a side wall that extends from the base to the first major surface, forming a first dielectric layer on the side wall of the trench; forming a bottom dielectric on the base of the trench, forming a first intermediate dielectric layer on the undoped polysilicon, forming a field plate on the first intermediate dielectric layer, wherein the field plate comprises an upper portion with a width W1 and a lower portion with a width W2, wherein W1 > W2, forming a second intermediate dielectric layer on the field plate, forming a gate electrode on the second intermediate dielectric layer. The bottom dielectric has a first thickness that is measured in a first direction that is orthogonal to the base of the trench and the first dielectric layer has a second thickness that is measured in a second direction that is orthogonal to the side wall of the trench. The first thickness is greater than the second thickness.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIGS. 1A to 1F illustrate cross-sectional views of semiconductor devices according to various embodiments.

FIGS. 2A to 2E illustrate a method of fabricating a semiconductor device.

FIGS. 3A to 3C illustrate a method for fabricating a dielectric structure in a trench.

FIGS. 4A to 4I illustrate a method for forming a dielectric structure in a trench.

FIGS. 5A to 5I illustrate a method of fabricating a dielectric structure in a trench.

FIGS. 6A to 6E illustrate a method of forming a gate electrode in a trench.

### DETAILED DESCRIPTION

In the following detailed description, reference is made to the accompanying drawings, which form a part hereof, and in which is shown by way of illustration specific embodiments in which the invention may be practiced. In this regard, directional terminology, such as "top", "bottom", "front", "back", "leading", "trailing", etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, "lateral" or "lateral direction" should be understood to mean a direction or extent that runs generally parallel to the lateral extent of a semiconductor material or semiconductor carrier. The lateral direction thus extends generally parallel to these surfaces or sides. In contrast thereto, the term "vertical" or "vertical direction" is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The figures illustrate relative doping concentrations by indicating "-" or "+" next to the doping type "n" or "p". For example, "n⁻" means a doping concentration which is lower than the doping concentration of an "n"-doping region while an "n⁺"-doping region has a higher doping concentration than an "n"-doping region. Doping regions of the same relative doping concentration do not necessarily have the same absolute doping concentration. For example, two different "n"-doping regions may have the same or different absolute doping concentrations.

The trench in which the field plate is arranged may have an elongate stripe -like form having a length which extends parallel to the first major surface, its length being greater than its depth from the first major surface and which is in turn greater than its width.

In some embodiments, the semiconductor device is a transistor device. The transistor device may be a MOSFET (Metal Oxide Semiconductor Field Effect Transistor) device, an insulated gate bipolar transistor (IGBT) device or a Bipolar Junction Transistor (BJT).

The electrodes or terminals of the transistor device are referred to herein as source, drain and gate. As used herein, these terms also encompass the functionally equivalent terminals of other types of transistor devices, such as an insulated gate bipolar transistor (IGBT). For example, as used herein, the term “source” encompasses not only a source of a MOSFET device and of a superjunction device but also an emitter of an insulator gate bipolar transistor (IGBT) device and an emitter of a Bipolar Junction Transistor (BJT) device, the term “drain” encompasses not only a drain of a MOSFET device or of a superjunction device but also a collector of an insulator gate bipolar transistor (IGBT) device and a collector of a BJT device, and the term “gate” encompasses not only a gate of a MOSFET device or of a superjunction device but also a gate of an insulator gate bipolar transistor (IGBT) device and a base of a BJT device.

The output charge figure-of-merit FOMoss = RDS(on) x Qoss represents a synthetic indicator of how well a transistor device behaves in conduction and switching. Losses associated with Qoss are increasingly important at high drain voltages, and scale linearly with the switching frequency. In order to improve the efficiency of a transistor device and reduce FOMoss, it is proposed to provide a low voltage trench-based MOSFET with a stepped field dielectric and a thick bottom dielectric.

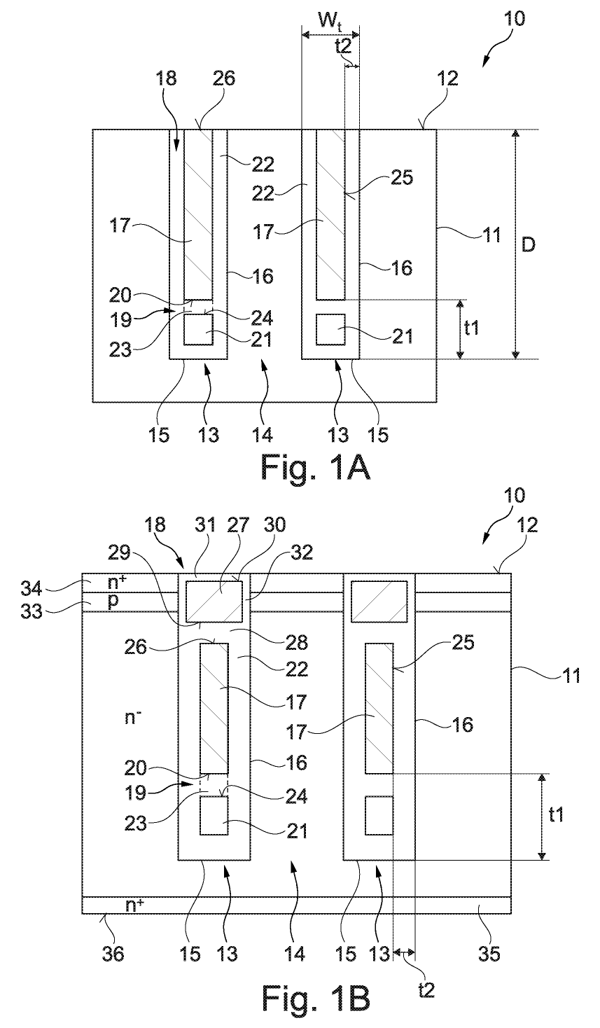

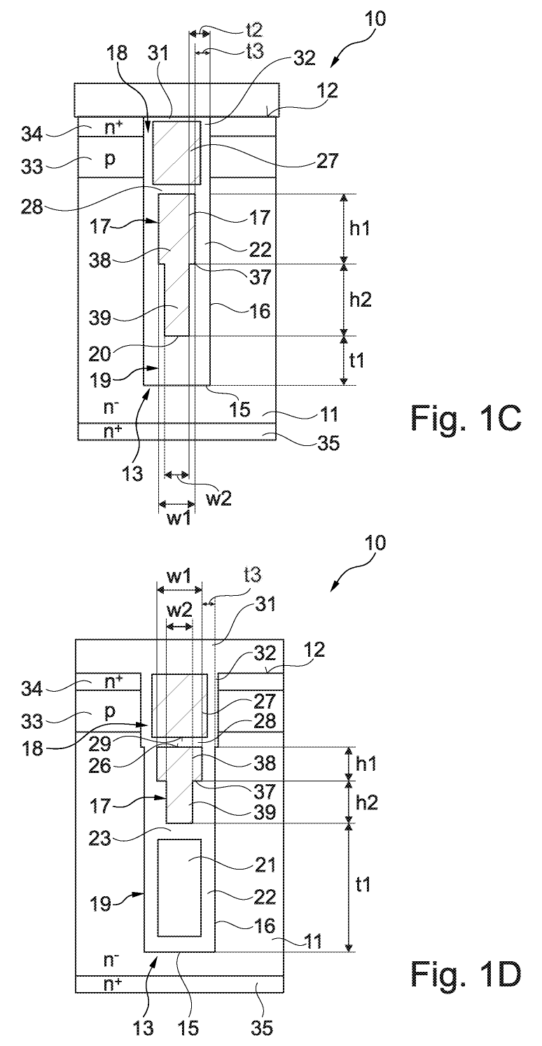

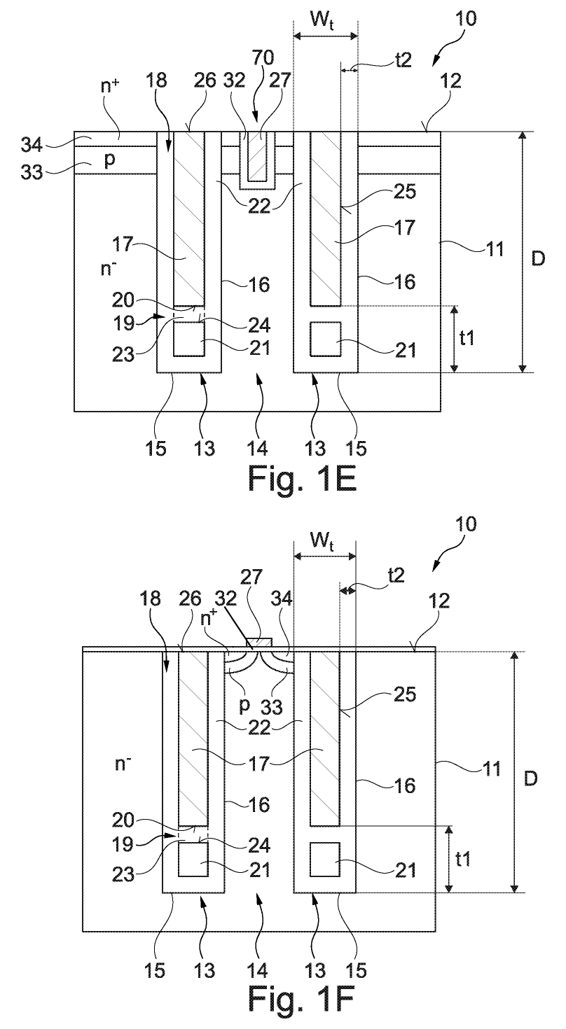

FIGS. 1A to 1F illustrate cross-sectional views of semiconductor devices 10 according to various embodiments.

In FIGS. 1A to 1F, the semiconductor device 10 of each of the embodiments comprises a semiconductor substrate 11 comprising a first major surface 12. The semiconductor substrate 11 may be formed of silicon, for example an epitaxial silicon layer. At least one trench 13 is formed in the first major surface 12 of the semiconductor substrate 11. The trench 13 has a stripe-like elongated form with its longest direction extending into the plane of the drawing. The shape of the trench 13 in top view is rectangular. FIGS. 1A to 1F illustrate two trenches 13 which are laterally spaced apart from one another by a portion of the semiconductor substrate 11 which may be referred to as a mesa 14. The trenches 13 extend substantially parallel to one another such that the mesa 14 has an elongate strip-like shape with a substantially uniform width. The mesa 14 is formed between facing side faces 16 of neighbouring trenches 13. The semiconductor device 10 may include a large number of such trenches 13 and mesas 14, e.g. hundreds or thousands.

FIG. 1A shows an example, where an electrode 17 is arranged in the trench 13. This electrode may be a gate electrode or a field plate. FIGS. 1B to 1D show examples, where both a field plate and a gate electrode is present in the semiconductor device 10.

Each of the trenches 13 comprises a base 15 and a sidewall 16 which extends from the base 15 to the first major surface 12. In an embodiment, each of the trenches 13 has an elongate stripe-like shape with the length extending into the plane of the drawing and has a substantially uniform width so that the side wall 16 has two opposing long side wall sections, which can be seen in the cross-sectional view of FIGS. 1A to 1F. A field plate 17, which is electrically conductive, is located in the trench 13. The field plate 17 also has an elongate stripe-like shape. A dielectric structure 18 is also located in the trench 13. The field plate 17 is electrically insulated from the semiconductor substrate 11 by the dielectric structure 18. The dielectric structure 18 comprises a bottom dielectric 19 which extends between the base 15 and a lower surface 20 of the field plate 17.

Referring to FIG. 1A, the bottom dielectric 19 of the semiconductor device 10 of this embodiment comprises a slightly doped polysilicon member 21. The slightly doped polysilicon member 21 is formed of polysilicon. The polysilicon of the slightly doped polysilicon member 21 may comprise p-type dopants. The slightly doped polysilicon member 21 is electrically insulating and provides a dielectric material which forms part of the dielectric structure 18. According to some examples, the slightly doped polysilicon member 21 is electrically floating and is not connected to the source contact. The slightly doped polysilicon member 21 may have a doping level of less than 10¹⁸cm⁻³, for example less than 10¹⁴cm⁻³. The field plate 17 is electrically conductive and, in some embodiments, is formed of highly doped polysilicon. The doping concentration of the polysilicon of the field plate 17 is at least 10²⁰cm⁻³ and, therefore, is higher than the slightly doped polysilicon member 21 of the bottom dielectric.

In some embodiments, the polysilicon of the slightly doped polysilicon member 21 is not intentionally doped and includes only residual dopants arising from the processing equipment or environment. In these embodiments, the slightly doped polysilicon member 21 may also be referred to an unintentionally doped or undoped. Polysilicon can be deposited as amorphous silicon or polysilicon. After annealing, amorphous silicon will start to crystallize into polysilicon. As deposited, the silicon is intended to be undoped, however, residual levels of dopant from the furnace or atmosphere can be incorporated or absorbed resulting low doping levels of the polysilicon. This residual or unintentional doping level is lower than 10¹⁴cm⁻³, for example.

The dielectric structure 18 further comprises a dielectric liner layer 22 which is located on the sidewall 16 and the base 15 of the trench 13. The slightly doped polysilicon member 21 is positioned on the dielectric liner layer 22 that is located on the base 15. The polysilicon member 21 extends between the inner surface of the dielectric liner layer 22 located on opposing side wall sections of the sidewall 16 of the trench 13 in the lower portion of the trench 13 at positions adjacent the base 15 of the trench 13. The dielectric structure 18 further comprises a first intermediate dielectric layer 23 which is arranged on the upper surface 24 of the slightly doped polysilicon member 21 and extends between the upper surface 24 of the slightly doped polysilicon member 21 and the lower surface 20 of the field plate 17. Thus, the field plate 17 is electrically insulated from the semiconductor substrate 11 by the dielectric structure 18 which comprises the dielectric liner layer 22, the first intermediate layer 23 and the slightly doped polysilicon member 21. The slightly doped polysilicon member 21 is entirely surrounded and encapsulated by the dielectric liner layer 22 and the first intermediate layer 23.

The portion of the dielectric liner layer 22 that is located in planes under the field plate 17, the slightly doped polysilicon member 21 and the first intermediate layer 23 together form the bottom dielectric 19 of the dielectric structure 18. In an embodiment, the dielectric liner layer 22 and the first intermediate layer 24 are formed of an oxide, for example silicon oxide and the slightly doped polysilicon member 21 has a doping concentration of less than 10¹⁸cm⁻³. The slightly doped polysilicon member 21 is entirely surrounded and encapsulated by oxide material, e.g. silicon oxide.

The bottom dielectric 19 has a first thickness t1 which is measured substantially perpendicularly to the base 15 of the trench 13 and is measured between the base 15 of the trench 13 and the lower surface 20 of the electrically conductive field plate 17. In some embodiments, the base 15 of the trench 13 is rounded. In these embodiments, the first thickness is measured at the deepest point of the base 15 from the first major surface 13.

The dielectric liner layer 22 has a second thickness t2 which is measured between the outer side face 25 of the field plate 17 and the sidewall 16 of the trench 13 in a direction that is substantially perpendicular to the side face 16 of the trench 13 and outer side face 25 of the field plate 17. In some embodiments, the side face 16 of the trench 15 extends substantially perpendicularly to the first major surface 12. In this embodiment, the thickness t2 of the dielectric liner layer 22 may be measured in a plane which is substantially parallel to the first major surface 12. In embodiments in which the side face 16 of the trench 13 extends substantially perpendicularly to the first major surface 12, the width of the trench 13 at the first major surface 12 is substantially uniform along the depth of the trench 13.

The thickness t2 may be measured in a plane that is halfway between the lower surface 20 and upper surface 26 of the field plate 17.

The thickness t1 of the bottom dielectric 19 is greater than the thickness t2 of the dielectric liner layer 22. For example, t1 may be greater or equal to 2 times t1, or greater or equal to 3 times t1, or greater or equal to 5 times t1. In an embodiment, 100 nm ≤ t1 ≤ 1000 nm and 10 nm ≤ t2 ≤ 100 nm. In an embodiment, 250 nm ≤ t1 ≤ 750 nm and 20 nm ≤ t2 ≤ 90 nm. In some examples, 50 nm ≤ t2 ≤ 200 nm.

In some embodiments, the trench 13 is tapered and has a greater width at the first major surface 12 than at its base 15. The thickness t2 may be measured in a plane that is half was between the lower surface 20 and upper surface 26 of the field plate 17.

In some embodiments, the trench 13 has a width Wt at the first major surface 12, wherein 100 nm ≤ Wt ≤ 340 nm, or 220 nm ≤ Wt ≤ 340 nm. The base 15 of the trench may lie at a depth D from the first major surface, wherein 1 µm ≤ D 1.3 µm.

In the embodiment illustrated in FIG. 1A, the field plate 17 has an upper surface 26 which is substantially coplanar with the first major surface 12. This enables an electrical contact to be formed to the field plate 17 more easily at any position along the length of the trench. In some embodiments, the upper surface 26 of the field plate 17 is located within the trench 13 and below the first major surface 12. The upper surface 17 of the field plate 17 may be covered by a further dielectric layer which may also extend over the first major surface 12. A contact to the field plate 17 may be formed by a conductive via that extends through this further dielectric layer.

The trench 13 including the field plate 17 and dielectric structure 18 may be used as a charge compensation device in a transistor device. This transistor device may have a gate trench comprising a gate electrode which is located in the mesa 14 Alternatively, the trench 13 including the field plate 17 and dielectric structure 18 may be used in other types of devices, for example a diode.

The trench 13 may have an elongate strip-like structure in plan view and have a length which extends parallel to the first major surface, the length being greater than its depth from the first major surface and the depth being greater than its width. In other embodiments, the trench has a columnar or needle type shape. A columnar or needle-shaped trench has a small or narrow circumference or width in proportion to its height / depth in the substrate, that it perpendicular to the first major surface. The cross-sectional structure of the columnar trench 13 corresponds to that of FIGS. 1A to 1F for the elongate trench 13.

Referring to FIG. 1B, in some embodiments, the semiconductor device 10 further comprises a gate electrode 27 that is formed in the trench 13 and located above the field plate 17. The gate electrode 27 and the field plate 17 have an elongate stripe-like form. The gate electrode 27 is spaced apart from the upper surface 26 of the field plate by a second intermediate dielectric layer 28 which extends between the upper surface 26 of the field plate 17 and the lower surface 29 of the gate electrode 27. The upper surface 30 of the gate electrode 27 may be positioned within the trench 13 and below the first major surface 12. An upper dielectric layer 31 which covers the upper surface 30 of the gate electrode 27 may be provided. The upper dielectric layer 31 may also extend over the first major surface 12 of the semiconductor substrate 11.

The gate electrode 27 is electrically insulated from the semiconductor substrate 11 by a gate dielectric 32 which is positioned on the side wall 16 of the trench 13 at positions laterally adjacent the gate electrode 27. The gate dielectric 32 has a thickness which is less than the thickness t2 of the dielectric liner layer 22 located on the sidewall 16 of the trench 13 at positions laterally adjacent the side faces 25 of the field plate 17. The bottom dielectric 19 of the dielectric structure 18 has a thickness t1 which is greater than the thickness t2 as in the semiconductor device of FIG. 1A. For example, t1 may be greater or equal to 2 times t1, or greater or equal to 3 times t1, or greater or equal to 5 times t1. The upper surface 26 of the field plate 17 may be located within the trench 13 at a further distance from the first major surface 12 compared to the embodiment illustrated in FIG. 1A so as to allow the gate electrode 27 to be formed in the upper part of the trench 13. In these embodiments, the semiconductor device 10 is a transistor device, for example a MOSFET.

In the semiconductor device 10 of embodiment described with reference to FIG. 1B, the second dielectric layer 28, the upper dielectric layer 31, the dielectric liner layer 22, the slightly doped polysilicon member 22, the first intermediate layer 23 and the gate dielectric 32 form the dielectric structure 18 in the trench 13. The second dielectric layer 28, the upper dielectric layer 31, the dielectric liner layer 22, the first intermediate layer 23 and the gate dielectric 32 may be formed of an oxide such as silicon oxide and the slightly doped polysilicon member 21 have a doping concentration of less than 10¹⁸cm⁻³. The ratio of t1 and t2 may be the same as in the devices illustrated in FIG. 1A. For example, t1 may be greater or equal to 2 times t1, or greater or equal to 3 times t1, or greater or equal to 5 times t1.

The semiconductor substrate 11 may be formed of silicon, for example an epitaxial silicon layer, and have a first conductivity type, for example n-type. The transistor device further comprises a body region 33 formed in the first major surface 12 which is formed of second conductivity type which opposes the first conductivity type of the semiconductor substrate 11. For example, the body region 33 is p-type if the semiconductor substrate 11 is n-type. A source region 34 of the first conductivity type is formed in and/or on the body region 33. A drain region 35 formed of the first conductivity type is formed at the second major surface 36 of the semiconductor substrate 11 which opposes the first major surface 12. The region of the semiconductor substrate 11 between the body region 33 and drain region 35 provides the drift region of the transistor device.

FIG. 1C illustrates a semiconductor device 10 which is similar to that of FIG. 1B and illustrates one trench 13 of the plurality of trenches 13 formed in the first major surface 12 of the semiconductor substrate 11. A gate electrode 27 is arranged in the trench 13 above the field plate 17. The dielectric structure 18 is located in the trench and electrically insulates the gate electrode 27 and the field plate 17 from each other and from the semiconductor substrate 11. Since the semiconductor device 10 comprises a gate electrode 27, the semiconductor device 10 provides a transistor device and further comprises a body region 33, a source region 34 and a drain region 35 as in the embodiment illustrated in FIG. 1B.

The dielectric structure 18 comprises a bottom dielectric 19 which extends between the lower surface 20 of the field plate 17 and the base 15 of the trench 13 and which has a thickness t1 which is greater than the thickness t2 of the dielectric structure at a position between the outer side face 25 of the field plate 17 and the sidewall 16 of the trench 13. The semiconductor device 10 illustrated in FIG. 1C differs from that illustrated in FIG. 1B in the shape of the field plate 17. The outer surface 25 of the field plate 17 has a step 37 which is located intermediate the height of the outer surface 17. Consequently, the field plate 17 has an upper portion 38 having a height h1 and a width W1 and a lower portion 39 having a height h2 and width W2. The overall height h of the field plate 17 is, therefore, h1+ h2. In an embodiment, 200 nm ≤ h ≤ 270 nm, 50 nm ≤ h1 ≤ 80 nm and 50 nm ≤ h2 ≤ 80 nm.

In some embodiments, the step 37 has an abrupt change in the width of the field plate 17 and consequently there is a corresponding abrupt change in the thickness of the dielectric liner layer 22. In other embodiments, the step 37 has a smooth transition between the greater width W1 and the smaller width W2. In other words, in the smooth transition, the transition between the thickness W1 and W2 takes place over a greater height than in the abrupt transition.

The width W1 of the upper portion 38 of the field plate 17 is greater than the width W2 of the lower portion 39 so that W1 > W2. Consequently, the dielectric liner layer 22 which is positioned on the sidewall 16 of the trench 13 has a smaller thickness t3 at a location which extends orthogonally to the outer surface 25 of the upper portion 38 of the field plate 17 and the sidewall 15. The thickness t2 is measured intermediate the height of the lower portion 39 and is measured orthogonally to the outer surface 25 of the lower portion 39 and the sidewall 15. The portion of the dielectric liner layer 22 which is located between the outer side surface 25 of the field plate 17 and the sidewall 15 of the trench 13 can be considered to have a stepped shape since the dielectric liner layer 22 and the field plate 17 fills the width of the trench 13. The arrangement of the dielectric layer 22 can be described as a stepped field dielectric. In this embodiment, the dielectric structure 18 may be formed of silicon oxide and is free of a slightly doped polysilicon member located in the bottom of the trench 13 between the base 15 of the trench 13 and the lower surface 20 of the field plate 17. The bottom dielectric 19 may be formed of one or more sublayers of silicon oxide, for example.

In an embodiment, 70 nm ≤ W1 ≤ 90 nm and 60 nm ≤ W2 ≤ 80 nm and W1 > W2. In an embodiment, 30 nm ≤ W3 ≤ 70 nm, wherein W2 > W3.

In an embodiment, 250 nm ≤ t1 ≤ 300 nm, 70 nm ≤ t2 ≤ 100 nm and 50 nm ≤ t3 ≤ 80 nm, wherein t3 < t2 < t1. In an embodiment, 50 nm ≤ t2 ≤ 200 nm and 50 nm ≤ t3 ≤ 200 nm, wherein t3 < t2 < t1.

FIG. 1D illustrates a semiconductor device 10 according to another embodiment which differs from that illustrated in FIG. 1C in that the bottom dielectric 19 comprises a slightly doped polysilicon member 21 which is located in the region between the lower surface 20 of the field plate 17 and the base 15 of the trench 13. The slightly doped polysilicon member 21 is electrically insulating and the spaced apart from the semiconductor substrate 11 by the dielectric liner layer 22 which lines the sidewall 16 and base 15 of the trench 13. The slightly doped polysilicon member 21 is spaced apart from the lower surface 20 of the field plate 17 by the first intermediate layer 23, as in the embodiment illustrated in FIG. 1B. The slightly doped polysilicon member 21 is entirely surrounded and encapsulated by the dielectric layers 22, 23 and in some embodiments is entirely surrounded and encapsulated by oxide material, e.g. silicon oxide, when the dielectric layers 22, 23 are formed of an oxide such as silicon oxide.

The field plate 17 comprises a step 37 intermediate the height of the field plate 17 as in the embodiment illustrated in FIG. 1C. Consequently, the field plate 17 has an upper portion 38 with a width W1 that is greater than the width W2 of the lower portion 39. The dielectric liner layer 22 on the side wall 16 of the trench also has a stepped shape and has a thickness t3 in locations laterally adjacent to the upper portion 39 of the field plate 17 that is less than the thickness t2 in locations laterally adjacent the lower portion 39 of the field plate 17. The thickness t2 of the dielectric layer 22 is less than the thickness t1 of the bottom dielectric 18. The ratio of t1 and t2 may be the same as in the devices illustrated in FIG. 1A. For example, t1 may be greater or equal to 2 times t1, or greater or equal to 3 times t1, or greater or equal to 5 times t1. In the embodiment illustrated in FIGS. 1C and 1D, a gate electrode 27 is also arranged in the trench 13 above the field plate 17 so that the semiconductor device 10 provides a transistor device. In other embodiments, the gate electrode 27 may be omitted. In these other embodiments, the field plate 17 may extend to the first major surface 12 or the upper surface 26 of the field plate 17 may be located within the below the first major surface 12 and within the trench 13.

If the semiconductor device 10 comprises a transistor device, the gate electrode 27 may not be located in the trench 13 along with the field plate 17. Other transistor device designs may also be used. In these other designs, the dielectric structure 18 includes the slightly doped polysilicon member located between the lower surface 20 of the field plate 17 and the dielectric layer 22 located on the base 15 of the trench.

FIG. 1E illustrates a semiconductor device 10 comprising a transistor device according to an embodiment. In this transistor device design, the gate electrode 27 is located in a separate gate trench 70 that is positioned in the mesa 14. The gate trench 70 extends into the semiconductor substrate 11 from the first major surface 12 and is spaced apart from the side walls 16 of the neighbouring trenches 13 which define the width of the mesa 14. The gate trench 37 is lined with a gate dielectric layer 32. The depth of the gate trench 70 is less than the depth of the trenches 13. The dielectric structure 18 of the trench 13 may be that of any one of the embodiments described herein.

FIG. 1F illustrates a semiconductor device 10 comprising a transistor device according to an embodiment. In this transistor device design, the gate electrode 27 is a planar gate and is located on the first major surface 12 above the mesa 14. The planar gate 27 is spaced apart from the upper surface 12 of the mesa 14 by a dielectric layer 32 that serves as the gate dielectric. The planar gate 27 is spaced apart from the two neighbouring trenches13 and is located approximately midway between the side walls 16 of the neighbouring trenches 13. The dielectric structure 18 of the trench 13 may be that of any one of the embodiments described herein.

In the embodiments illustrated in FIGS. 1A to 1F, the dielectric liner layer 22 includes a single layer, for example an oxide such as silicon oxide. In other embodiments, which are not illustrated in FIGS. 1A to 1F, the dielectric liner layer 22 comprises two or more sublayers. The two or more sublayers may be formed of the same material, e.g. silicon oxide, or may have differing compositions. In one embodiment, the dielectric liner 22 comprises a first sublayer formed of an oxide which is located directly on the side face 16 and base 15 of the trench 13, a second sublayer formed of a nitride, which is located directly on the first sublayer, and a third sublayer formed of an oxide which is located directly on the second sublayer. In an embodiment, the first and third sublayers are formed of silicon oxide and the second sublayer is formed of silicon nitride.

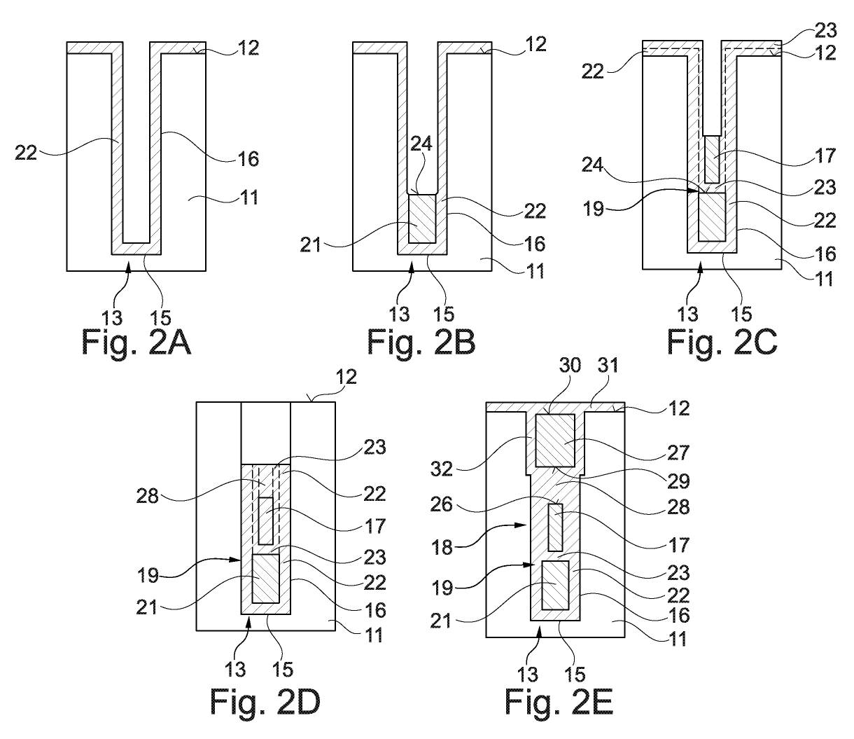

FIGS. 2A to 2E illustrate a method of fabricating a semiconductor device. The method illustrated and described with reference to FIGS. 2A to 2E may be used to fabricate the semiconductor device illustrated in FIG. 1A and the transistor device illustrated in FIG. 1B, for example.

Referring to FIG. 2A, a semiconductor substrate 11 is provided which has a first major surface 12. The semiconductor substrate 11 may be formed of silicon and may be formed of silicon epitaxial layer or a monocrystalline silicon substrate, such as a silicon wafer. At least one trench 13 is formed in the first major surface 12. The trench 13 may have an elongate stripe -like structure with its length (longest direction) extending into the plane of the drawing. In FIGS. 2A to 22E, a single trench 13 is shown for illustrative purposes. The semiconductor device 20 typically includes a plurality of trenches 13 which extend substantially parallel to one another and a stripe-like elongate mesa 14 is formed between neighbouring ones of the trenches 13. Each of the trench 13 has a base 15 and the sidewall 16 which extends from the base 15 to the first major surface 12. A first dielectric layer 22 is formed on the sidewall 16 and base 15 so as to line the trench 13. The first dielectric layer 22 may also be formed over the first major surface 12. The first dielectric layer 22 may be formed of an oxide, for example silicon oxide.

In some embodiments, the first dielectric layer 22 is formed by thermal oxidation of the exposed surfaces of the trench 13 and exposed first major surface 12. In some embodiments, the first dielectric layer 22 may be a deposited layer, for example deposited using a TEOS (Tetra-Ethyl-Ortho Silicate) process. In some embodiments, the first dielectric layer 22 may have two or more sublayers. For example, a first sublayer may be formed by thermal oxidation and a second sublayer may be formed on the first sublayer by deposition, e.g. using a TEOS process.

Referring to FIG. 2B, slightly doped polysilicon material 21 is inserted into the trench 13 and fills the gap formed between the inner surfaces of the first dielectric layer 22 at the base 15 of the trench 13 to form a polysilicon member 21. Slightly doped polysilicon material 21 is useful for this purpose as can be selectively etched over silicon oxide which can be used for the first dielectric layer 22. In some embodiments, the slightly doped polysilicon material may initially fill the trench 13 and over the first major surface. A planarization process, e.g. chemical mechanical polishing (CMP) may be carried out and the slightly doped polysilicon material from the first major surface and then the slightly doped polysilicon removed from the trench 13 so that the upper surface is located within the trench 13. In this embodiment, the upper surface 24 of the polysilicon member 21 is located within the lower half or lower third of the trench 13. The polysilicon member 21 is slightly doped and electrically insulating. The polysilicon member 21 may have a doping concentration of less than 10¹⁸cm⁻³.

Referring to FIG. 2C, a second dielectric layer 23 is deposited onto the upper surface 24 of the slightly doped polysilicon member 21 and also onto the first dielectric layer 22 located on the sidewall 16 of the upper portion of the trench 13, i.e. between the upper surface 24 of the slightly doped polysilicon member 21 and the first major surface 12, and onto the first major surface 12. The second dielectric layer 23 may be formed of silicon oxide and surrounds a recess or gap in the centre of the upper portion of the trench 13. The second dielectric layer 23 may be deposited using a TEOS process. Conductive material for forming the field plate 17 is then inserted into this gap. The conductive material may comprise highly doped polysilicon so as to provide an electrically conductive field plate 17. The highly doped polysilicon may have a doping concentration of at least 10²⁰cm⁻³. The upper surface 24 of the field plate 17 is positioned within the trench 13. In embodiments in which the trench 13 is to include a gate electrode, such as the embodiment illustrated in FIG. 1B, the upper surface 24 of the field plate 17 is located at depth from the first major surface 12 so as to allow for the height of the second intermediate layer 28 and the height of the gate electrode 27.

Referring to FIG. 2D, a third dielectric material 28 is formed in the trench 13 so as to cover the field plate 17. The third dielectric material 28 may be deposited using HDP CVD (High Density Plasma Chemical Vapour Deposition). The dielectric layers 22, 23, 28 are then removed entirely from the side wall 16 of the trench 13 in the upper portion of the trench 13. The field plate 17 remains covered by the third dielectric material 28 so that the upper surface of the third dielectric material 28 on the field plate is located at a depth in the trench 13 from the first major surface 12 that corresponds to the desired position of the lower surface of the gate electrode 27.

Referring to FIG. 2E, the gate dielectric 32 is then formed on these exposed regions of the sidewall 16, for example by thermal oxidation or by deposition. If the gate dielectric 32 is formed by thermal oxidation of the side wall 16 of the trench, the width of the trench 13 is greater in positions adjacent the thermally grown gate dielectric that in positions laterally adjacent with the field plate 17, due to the consumption of the material of the semiconductor substrate 11 forming the side wall in the oxidation process. Silicon oxide is formed in the thermal oxidation process for a silicon semiconductor substrate 11. Electrically conductive material, e.g. high doped polysilicon or metal, is then inserted into the trench 13 to form the gate electrode 27. In some embodiments, the upper surface 30 of the gate electrode 27 is positioned within the trench 13 and below the first major surface 12. An upper dielectric 31 layer may be formed on the first major surface 12 and also on the upper surface of the gate electrode 27.

Subsequently, the body region and source region of the transistor device may be formed by implantation of dopants of a second and first conductivity type, respectively.

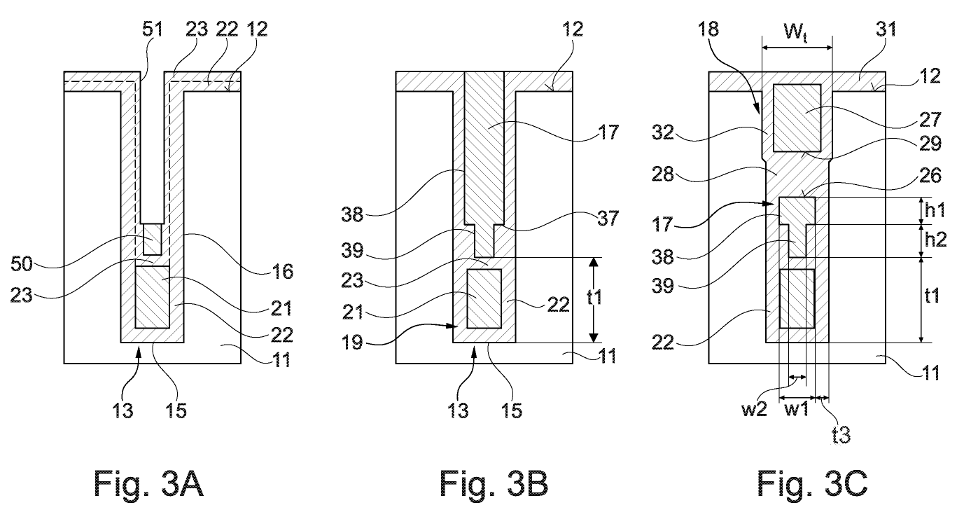

FIGS. 3A to 3C illustrate a method for fabricating a dielectric structure in a trench according to another embodiment. The method described with reference to FIGS. 3A to 3C is used to fabricate a stepped field dielectric 22 and a field plate 17 with a step in its outer side face and may be used to fabricate the semiconductor device illustrated in FIG. 1D. The method described with reference to FIGS. 3A to 3C, may also be thought of as a variation of the method of FIGS. 2A to 2E, in which the straight field plate 17 of FIGS. 2A to 2E is replaced by a stepped field plate.

As described for the method with reference to FIGS. 2A to 2C, the method starts by forming at least one trench 13 in the first major surface 12 of the substrate 11, forming the first dielectric layer 22 over the first major surface 12 of the semiconductor substrate 11, the side face 16 and the base 15 of the trench 13, forming the slightly doped polysilicon member 21 on the first dielectric layer 22 on the base 15 of the trench, and the second dielectric layer 23 on the slightly doped polysilicon member 21, the side face 16 of the trench 13 and on the first major surface 12 of the semiconductor substrate 11. One of a plurality of trenches 13 of the semiconductor device 10 is shown in FIGS. 3A to 3C for illustrative purposes. In this embodiment, after forming the second dielectric layer 23 as shown in FIG. 2C, sacrificial material 50 is formed in the base of the recess formed in the trench 13, which is lined by the second dielectric layer 23. The sacrificial material 50 has a height which substantially corresponds to the desired height h2 of the lower portion of the field plate 17. The sacrificial material 50 is selected so as to be preferentially removable over the material of the second dielectric layer 22. For example, if the second dielectric layer 22 is formed of silicon oxide, the sacrificial material 50 may be undoped or slightly doped polysilicon, since undoped or slightly doped polysilicon can be selectively removed by wet etching over silicon oxide.

Referring to FIG. 3B, a portion of the second dielectric layer 23 which is uncovered by the sacrificial material 50 and located on the sidewall 16 of the trench 13 in the upper portion of the trench 13 is removed. A further portion of the first and second dielectric layers 22, 23 remains on the side face 16 of the trench 13 and has a reduced thickness compared to the thickness of the first and second dielectric layers 22, 23 in planes laterally adjacent to the sacrificial material 50. The sacrificial material 50 is then removed to form a recess 51 in the trench 13. The recess 51 has a lower portion having a smaller width than an upper portion. In order to form the field plate 17, conductive material is then inserted into the recess 51 and may fill the recess 51. In some embodiments, the conductive material extends to the first major surface 12.

Referring to FIG. 3C, the upper portion of the conductive material is removed such that the upper surface of the field plate 17 is located at the desired depth from the first major surface 12. The method then continues as described with reference to FIGS. 2D and 2E. The third dielectric layer 28 is formed in the trench so as to cover the upper surface 20 of the field plate 17. The first second and third dielectric layers 22, 23, 28 are removed from the uppermost portion of the side faces 16 completely, whilst the upper surface of the field plate 17 remains covered by the third dielectric layer 28. The gate dielectric 32 is formed on these exposed side wall 16 of the trench 13 by thermally oxidation or by deposition. Conductive material is then inserted into the trench 13 to form the gate electrode 27 within the trench 13. The gate electrode 27 extends between the gate dielectric 32 on the side wall 16 of the trench 13. In some embodiments, the upper surface 28 of the gate electrode 27 is positioned within the trench 13 and below the first major surface 12. An upper dielectric 31 layer may be formed on the first major surface 12 and also on the upper surface of the gate electrode 27.

The body region 33 and source region 34 may be formed by implantation of appropriate dopants into the first major surface to form the transistor structure. The drain region 35 is located at the second major surface 36 of the semiconductor substrate 11.

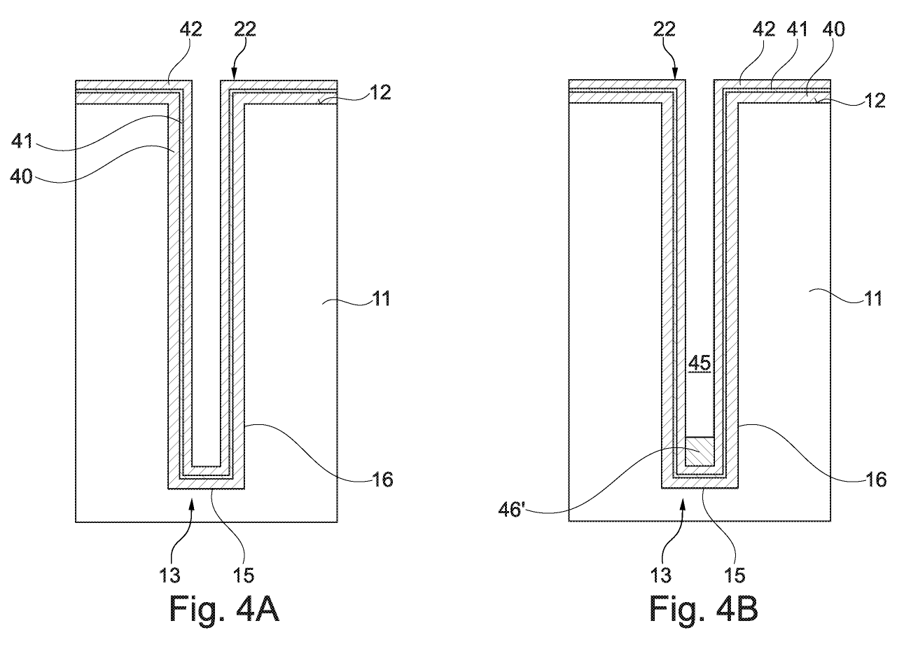

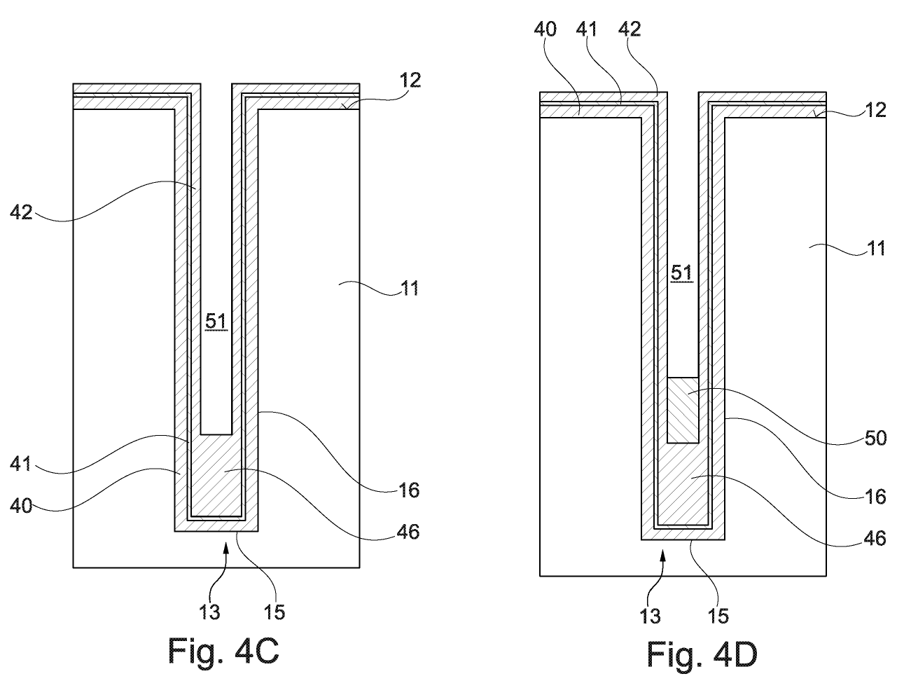

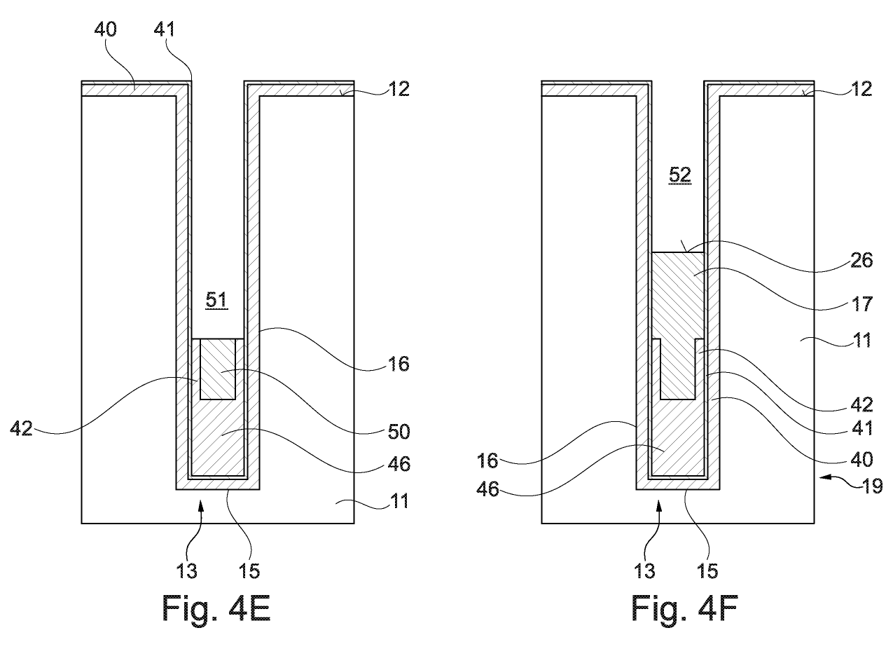

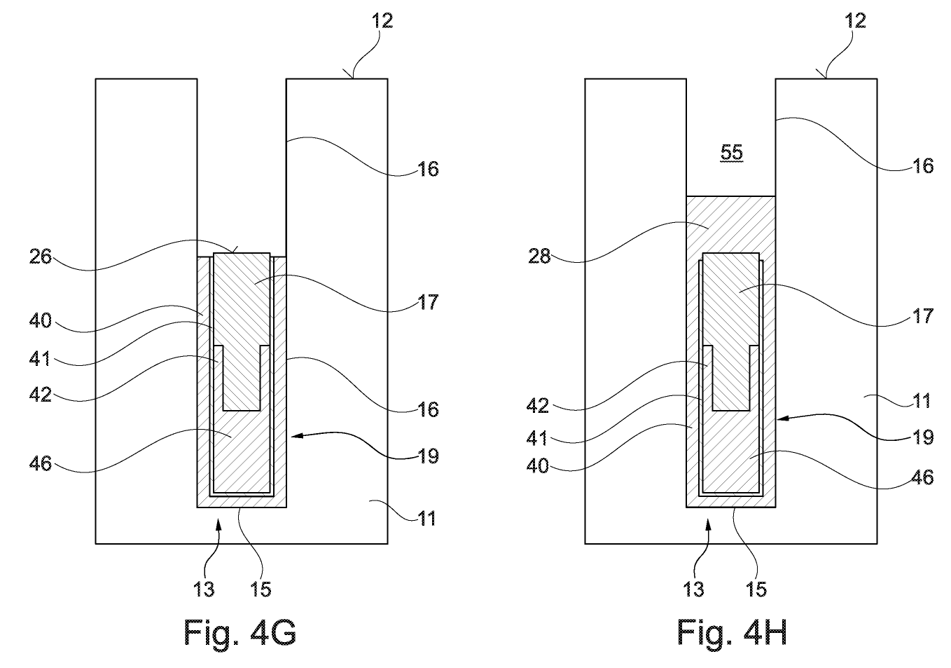

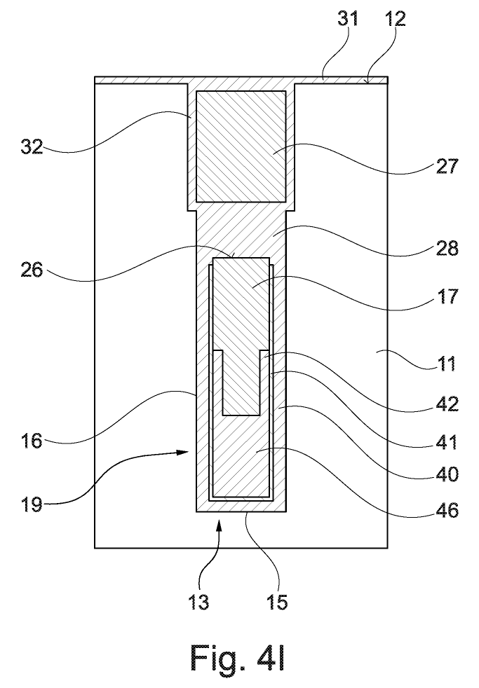

FIGS. 4A to 4I illustrate a method for forming a dielectric structure in a trench according to an embodiment. The method described with reference to FIGS. 4A to 4I differs from that described with reference to FIGS. 3A to 3C in the structure of the dielectric liner layer 22.

Referring to FIG. 4A, at least one trench 13 is formed in the first major surface 12 of the semiconductor substrate 11 as in the embodiments illustrated in FIGS. 2 and 3. One of a plurality of trenches 13 of the semiconductor device 10 is shown in FIGS. 3A to 3C for illustrative purposes. In this embodiment, the dielectric liner layer 22 includes three sublayers. Referring to FIG. 4A, a first sublayer 40 formed of an oxide, e.g. silicon oxide, is e.g. formed on the sidewall 16 and base 15 of the trench and also on the first major surface 12. A second sublayer 41 formed of nitride, such as silicon nitride, is formed on the first sublayer 40 on the sidewall 16 and base 15 of the trench and on the first major surface 12 of the semiconductor substrate 11. Subsequently, a third sublayer 42 is formed on the second sublayer 41 on the sidewall 16 and base 15 of the trench 13 and on the first major surface 12 of the semiconductor substrate. The third sublayer 42 comprises a dielectric material, such as an oxide, e.g. silicon oxide and may be deposited using TEOS.

In an embodiment, the second sublayer 41 has a different composition from the first and third sublayers 40, 42 which are selected such that the outer third sublayer 42 is selectively removable over the underlying second sublayer 41 and the second sublayer 41 is selectively removable over the underlying first sublayer 40 by wet etching and by the selection of a suitable wet etch.

The combination of silicon oxide for the first sublayer 40, silicon nitride for the second sublayer 41 and silicon oxide for the third sublayer 42 enables the outer third sublayer 42 to be selectively removed over the underlying second sublayer 41 and the second sublayer 41 to be selectively removed over the underlying first sublayer 40 by wet etching and by the selection of a suitable wet etch.

Referring to FIG. 4B, the third sublayer 42 bounds a recess 45 in the trench 13. In this embodiment, the final semiconductor device 10 includes a dielectric structure 18 with a bottom dielectric 19 formed at the base of the trench 13 which has a greater thickness t1 than the thickness t2 of the dielectric structure 18 on the sidewall 16 of the trench 13. In order to form this thick bottom dielectric 19, highly n-doped or slightly n-doped polysilicon 46’ is inserted into the base of the trench 13. As shown in FIG. 4C, this highly n-doped or slightly n-doped polysilicon 46’ is then oxidised so as to form electrically insulating material 46 which fills the lower portion of the trench 13. Highly n-doped polysilicon material oxidises more rapidly than slightly n-doped polysilicon. The stack of the first, second and third sublayers 40, 41, 42 located on the first major surface 12 of the mesa protects this surface 12 during the oxidation process. In the final dielectric structure 18, bottom dielectric 19 in the lower portion of the trench 13 under the field plate 17 comprises an oxide 46 which is bounded on its side faces and base by the second nitride sublayer 41 which is in turn surrounded by the first sublayer 40 which lines the side wall 16 and base 15 of the trench 13. The upper portion of the trench 13 comprises a recess 51.

Referring to FIG. 4D, sacrificial material 50 is inserted into the base of the recess 51 and fills the lower portion of the recess. The height of the sacrificial material 50 may correspond to the desired height h2 of the lower portion of the field plate 17. The sacrificial material 50 may be undoped polysilicon or slightly doped polysilicon, for example.

Referring to FIG. 4E, the third sublayer 42 is removed from the second nitride sublayer 41 in the region of the trench 13 which is positioned above the sacrificial material 50 and from the first major surface 12, thus exposing the second sublayer 41 formed of nitride. For example, the third sublayer 42 may be removed by selective etching of the oxide of the third sublayer 42 over the nitride of the underlying second sublayer 41. In some examples, the selectivity of the material of the third sublayer 42 over the material of the second sublayer 41 may be around 100 to 1.

Subsequently, the sacrificial material 50 is removed, as shown in FIG. 4F. The recess 52 formed by the removal of the sacrificial material 50 has an upper portion that is bounded on its side face by the second sublayer 41 and a lower adjoining section that is bounded by the third sublayer 42. The lower portion has a smaller width than the upper portion. Conductive material is inserted into the trench 13 and recess 52 to form the field plate 17. Thus, the field plate 17 is formed with a wider upper portion and a narrower lower portion. The upper portion of the field plate 17 has side faces that are in contact with the second sublayer 41 and the lower portion of the field plate 17 is entirely surrounded by oxide material of the third sublayer 42 and the oxide 46 formed by oxidizing the doped polysilicon material 46’

In some embodiments, the conductive material may initially fill the trench 13 and, subsequently, the upper portion of the conductive material is removed such that the upper surface 26 of the field plate 17 is located below the first major surface 12 in the desired plane and such that the upper portion of the field plate 17 has the desired height h1. In embodiments in which the trench 13 further comprises a gate electrode 27, as shown in FIG. 4F, the upper portion of the trench 13 at this stage comprises a recess 52 having a base formed by the upper surface 26 of the field plate 17 and sidewalls formed by the second sublayer 41 of the first dielectric layer 22 which is formed of nitride.

Referring to FIG. 4G, the method continues by removing the exposed region of the second sublayer 41 located on the side wall16 of the trench 13 and the first sublayer 40 such that the sidewall 16 above the field plate 17 and the first major surface 12 are exposed. An uppermost portion of the first sublayer 40 and of the second sublayer 41 that are located adjacent the field plate 17 may also be removed so that the upper surface 26 of the field plate 17 protrudes above the remaining portion of the dielectric layer 22.

Referring to FIG. 4H, a second intermediate dielectric layer 28 is formed in the trench 13 such that the upper surface 26 of the field plate 17 is covered by the dielectric layer 28. The side wall 16 of the trench 13 in the uppermost portion above the dielectric layer 28 and the first major surface 12 is exposed. The second intermediate dielectric layer 28 may be deposited using high density plasma deposition so that dielectric material also covers the first major surface 12. A planarization process followed by an etch process may be used to define the hight of the second intermediate layer 28 and expose the sidewall 16 in the upper portion of the trench 13 above the second intermediate layer 28. The second intermediate dielectric layer 28 forms the base of a recess 55 for the gate electrode.

Referring to FIG. 4I, a gate dielectric 32 for the gate electrode may be formed by oxidizing the exposed side wall 16. In some embodiments, a further dielectric layer is deposited onto the side wall 16 to form the gate dielectric 32.Conductive material is then inserted into this recess 55 to form the gate electrode 27.

Referring to FIG. 4I, the upper surface 30 of the gate electrode 27 may be located below the first major surface 12 and a capping dielectric layer 31 is formed on the first major surface 12 which also covers the upper surface of the gate electrode 27. The capping dielectric layer 31 may be formed of silicon oxide.

In the final semiconductor device 10, the dielectric structure 18 located in the region of the trench 13 located above the field plate 17 comprises only oxide, whereas in the portion of the trench 13 below the upper surface 26 of the field plate 17, the dielectric structure 18 includes the second nitride sublayer 41 which is in direct contact with the side face of the upper portion of the field plate 17 and which is spaced apart from the side face of the lower portion of the field plate 17 by the third sublayer 42. The nitride sublayer 41 has a U-shape in cross-section. The vertical section is in contact with the field plate 17 in an upper section and that is in contact with the first and third sublayers 40, 42 in a middle section and is in contact with the first sublayer 40 and the oxide 46 formed by oxidizing the slightly doped polysilicon in its lower section. The base of the U-shape is in contact with the first sublayer 40 and the oxide formed by oxidizing the slightly doped polysilicon.

The bottom dielectric 19 of the dielectric structure 18 formed at the base of the trench 13 which has a greater thickness t1 than the thickness t2 of the dielectric structure 18 located on the sidewall 16 of the trench 13.

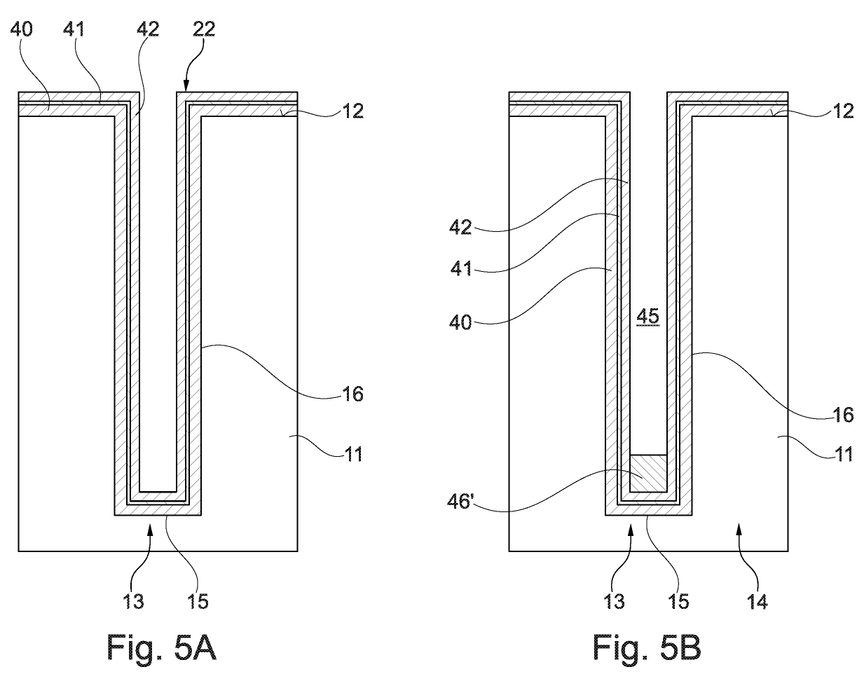

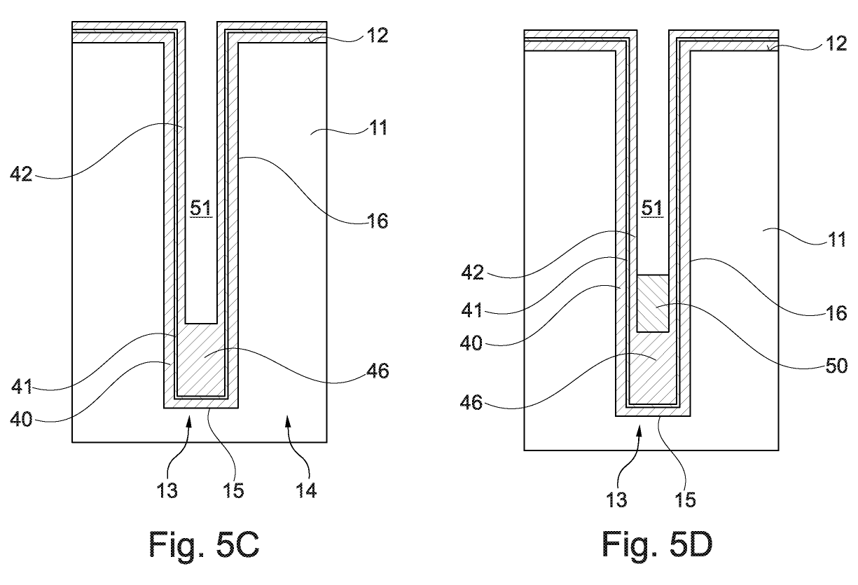

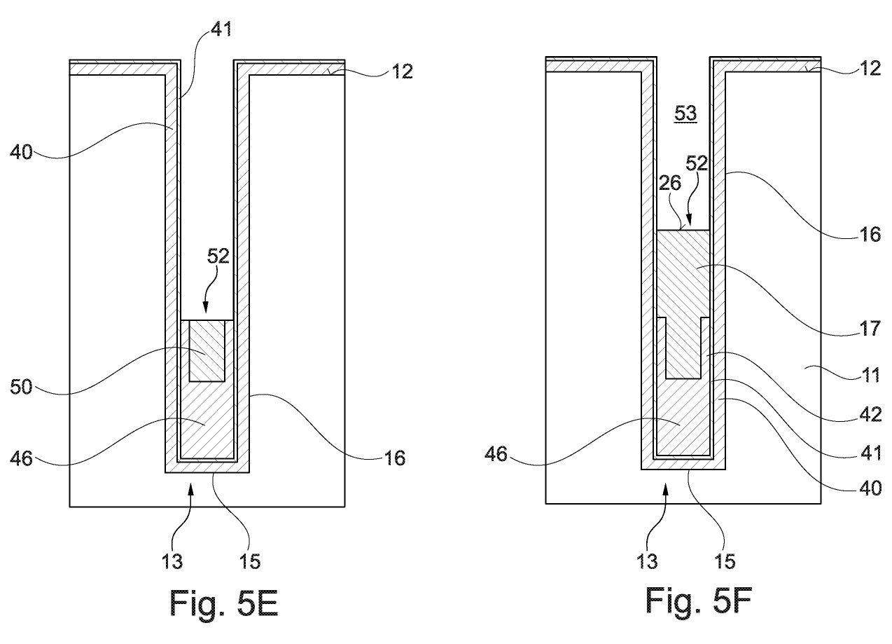

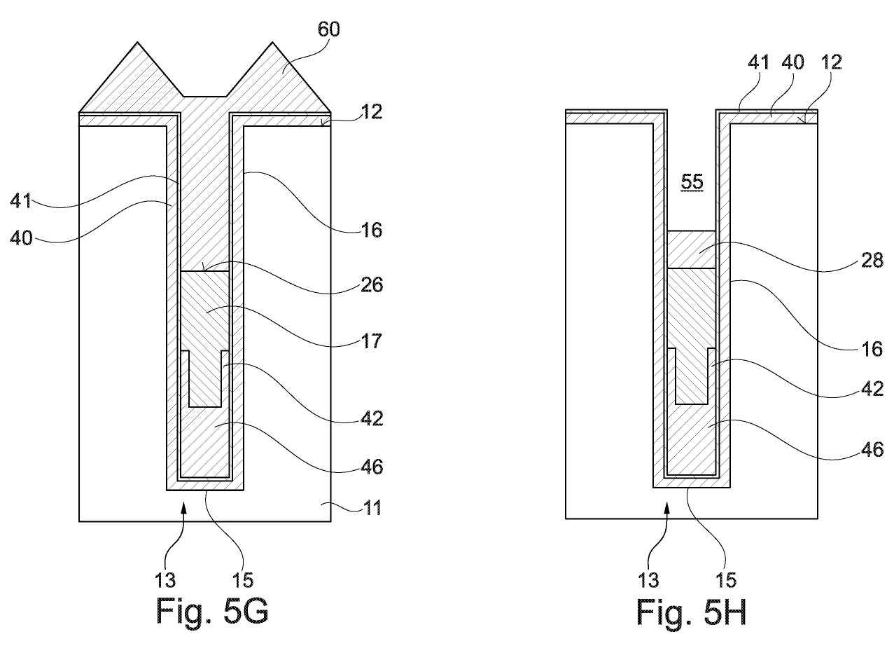

FIGS. 5A to 5I illustrate a method of fabricating a dielectric structure in a trench according to another embodiment. The method of described with reference to FIGS. 5A to 5F corresponds to the method illustrated with reference to FIGS. 4A to 4F.

Referring to FIG. 5A, at least one trench 13 is formed in the first major surface 12 of the semiconductor substrate 11 as in the embodiments illustrated in FIGS. 2 and 3. One of a plurality of trenches 13 of the semiconductor device 10 is shown in FIGS. 3A to 3C for illustrative purposes. In this embodiment, the dielectric liner layer 22 includes three sublayers. Referring to FIG. 4A, a first sublayer 40 formed of an oxide, e.g. silicon oxide, is e.g. formed on the sidewall 16 and base 15 of the trench and also on the first major surface 12. A second sublayer 41 formed of nitride, such as silicon nitride, is formed on the first sublayer 40 on the sidewall 16 and base 15 of the trench and on the first major surface 12 of the semiconductor substrate 11. A third sublayer 42 of dielectric material, such as an oxide, e.g. silicon oxide, is formed on the second sublayer on the base 15 and side wall 16 of the trench 13 and also extends over the first major surface 12 of the semiconductor device 11.

In an embodiment, the second sublayer 41 has a different composition from the first and third sublayers 40, 42 which are selected such that the outer third sublayer 42 is selectively removable over the underlying second sublayer 41 and the second sublayer 41 is selectively removable over the underlying first sublayer 40 by wet etching and by the selection of a suitable wet etch.

The combination of silicon oxide for the first sublayer 40, silicon nitride for the second sublayer 41 and silicon oxide for the third sublayer 42 enables the outer third sublayer 42 to be selectively removed over the underlying second sublayer 41 and the second sublayer 41 to be selectively removed over the underlying first sublayer 40 by wet etching and by the selection of a suitable wet etch.

Referring to FIG. 5B, the third sublayer 42 bounds a recess 45 in the trench 13. In this embodiment, the final semiconductor device 10 includes a dielectric structure 18 with a bottom dielectric 19 formed at the base of the trench 13 which has a greater thickness t1 than the thickness t2 of the dielectric structure 18 on the sidewall 16 of the trench 13. In order to form this thick bottom dielectric 19, slightly n-doped polysilicon or highly n-doped silicon 46’ is inserted into the base of the trench 13 and, as shown in FIG. 5C, oxidised so as to form electrically insulating material 46 which fills the lower portion of the trench 13. The location of the first, second and third sublayers 40, 41, 42 of the dielectric layer 22 on the first major surface hinders and may prevent the oxidation of the first major surface 12 that forms the upper surface of the mesa 14. In the final dielectric structure 18, bottom dielectric 19 in the lower portion of the trench 13 under the field plate 17 comprises an oxide 46 which is bounded on its side faces and base by the third sublayer 42 and the second nitride sublayer 41 which is in turn surrounded by the first sublayer 40 which lines the side wall 16 and base 15 of the trench 13. The upper portion of the trench 13 comprises a recess 51.

Referring to FIG. 5D, sacrificial material 50 is inserted into the base of the recess 51 and fills the lower portion of the recess. The height of the sacrificial material 50 may correspond to the desired height h2 of the lower portion of the field plate 17. The sacrificial material 50 may be slightly doped polysilicon, for example.

Referring to FIG. 5E, the third sublayer 42 is removed from the second nitride sublayer 41 in the region of the trench 13 which is positioned above the sacrificial material 50, thus exposing the second sublayer 41 formed of nitride. For example, the third sublayer 42 may be removed by selective etching of the oxide of the third sublayer 42 over the nitride of the underlying second sublayer 41. In some examples, the selectivity of the material of the third sublayer 42 over the material of the second sublayer 41 may be around 100 to 1.

Referring to FIG. 5F, subsequently, the sacrificial material 50 is removed. The recess 52 formed by the removal of the sacrificial material 50 has an upper portion that is bounded on its side face by the second sublayer 41 and a lower adjoining section that is bounded by the third sublayer 42. The lower portion has a smaller width than the upper portion. Conductive material is inserted into the trench 13 and recess 52 to form the field plate 17. Thus, the field plate 17 is formed with a wider upper portion and a narrower lower portion. The upper portion of the field plate 17 has side faces that are in contact with the second sublayer 41 and the lower portion of the field plate 17 is entirely surrounded by oxide material of the third sublayer 42 and the oxide 46 formed by oxidizing the slightly doped polysilicon material 46’

In some embodiments, the conductive material may initially fill the trench 13 and, subsequently, the upper portion of the conductive material is removed such that the upper surface 26 of the field plate 17 is located below the first major surface 12 in the desired plane and such that the upper portion of the field plate 17 has the desired height h1. In embodiments in which the trench 13 further comprises a gate electrode 27, as shown in FIG. 5F, the upper portion of the trench 13 at this stage comprises a recess 53 having a base formed by the upper surface 26 of the field plate 17 and sidewalls formed by the second sublayer 41 of the first dielectric layer 22 which is formed of nitride.

Referring to FIG. 5G, after the fabrication of the field plate 17 above the thick lower bottom dielectric 19, the second sublayer 41 formed of nitride extends to the first major surface 12 and lines the sidewalls of the recess 53 formed in the upper portion of the trench 13. The second sublayer 41 also extends over the first major surface 12. The base of the recess 53 is formed by the upper surface 20 of the field plate 17. The method illustrated in and described with reference to FIG. 5 differs from that described with reference to FIGS. 4A to 4I in that the recess 53 is then filled with dielectric material 60 which covers the second sublayer 41 and extends to the first major surface 12. The dielectric material 60 may be an oxide and may also extend over the first major surface 12.

Referring to FIG. 5H, a planarization process is then carried out. The second sublayer 41 located on the first major surface 12 may act as an etch stop during a chemical mechanical polishing planarization process. Then, the uppermost portion of the dielectric material 60 is removed from the upper portion of the trench 13 to a depth such that the upper surface 20 of the field plate 17 is covered by a remaining portion of the dielectric material 60 which forms the second intermediate layer 28. The dielectric material 60 may be removed by wet etching for example. The dielectric material 60 has a thickness such that its upper surface is positioned in a plane corresponding to the desired plane of the lower surface of the gate electrode 27. A recess 55 is formed which is bounded by the second sublayer 41 at the sidewalls of the recess 55 and the second intermediate layer 28 which forms the base of the recess 55. The second sublayer 41 is formed of nitride. The second sublayer 41 is then removed, for example by selective etching. Some or all of the underlying first sublayer 40 is also removed from the side walls of the recess 55.

Referring to FIG. 5I, to form a gate dielectric 32 on the side wall 16, an oxide layer is deposited on the exposed side wall 16 of the trench 13 or on any remaining portion of the first sublayer 40, which is also formed of an oxide. Electrically conductive material, e.g. doped polysilicon, is inserted into the trench to form the gate electrode 27. In this embodiment, the trench 13 has a width in the upper portion in a plane that is located adjacent the gate electrode 27 which is substantially the same as the width of the trench 13 at a position underneath the field plate 17. This shape of the trench 13 is formed as the gate dielectric 32 is formed by deposition of dielectric material onto the side wall and not by thermal oxidation of the side wall 16 of the trench 11 which is formed by the semiconductor substrate 11. This arrangement of the trench 13 having a substantially uniform width may be used to further reduce the pitch between neighbouring trenches 13 and reduce the width of the mesa 14 formed between neighbouring trenches 13.

In contrast, in the embodiment in the described with reference to FIGS. 4A to 4I, the width of the upper portion of the trench 13 laterally adjacent to the gate electrode 27 is wider than the width of the trench 13 at a vertical position below the field plate 17, since the gate dielectric 32 is formed by thermal oxidation of the silicon forming sidewall 16 of the trench 13. This thermal oxidation consumes silicon at the side wall16 and increases the width of the trench 13 defined by the distance between opposing silicon regions of opposing sections of the side wall 16.

Referring to FIG. 5I, the second sublayer 41 formed of nitride extends above the upper surface 26 of the field plate 17 and is in contact with the second intermediate layer 28 that is formed of an oxide. The second sublayer 41 is not located adjacent the gate electrode 27 and does not form a part of the gate dielectric 32.The gate dielectric 32 may be formed of an oxide, e.g. silicon oxide.

In some embodiments, an upper dielectric layer 32 is deposited which covers the upper surface of the gate electrode 27 and which may also extend over the first major surface 12 and form part of a metallization structure locate on the first major surface.

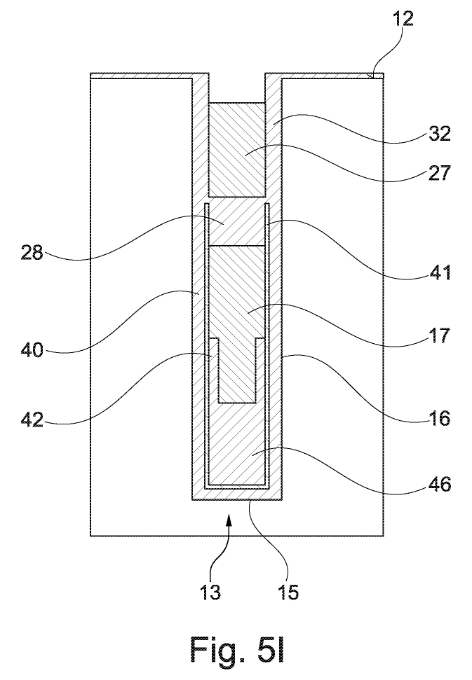

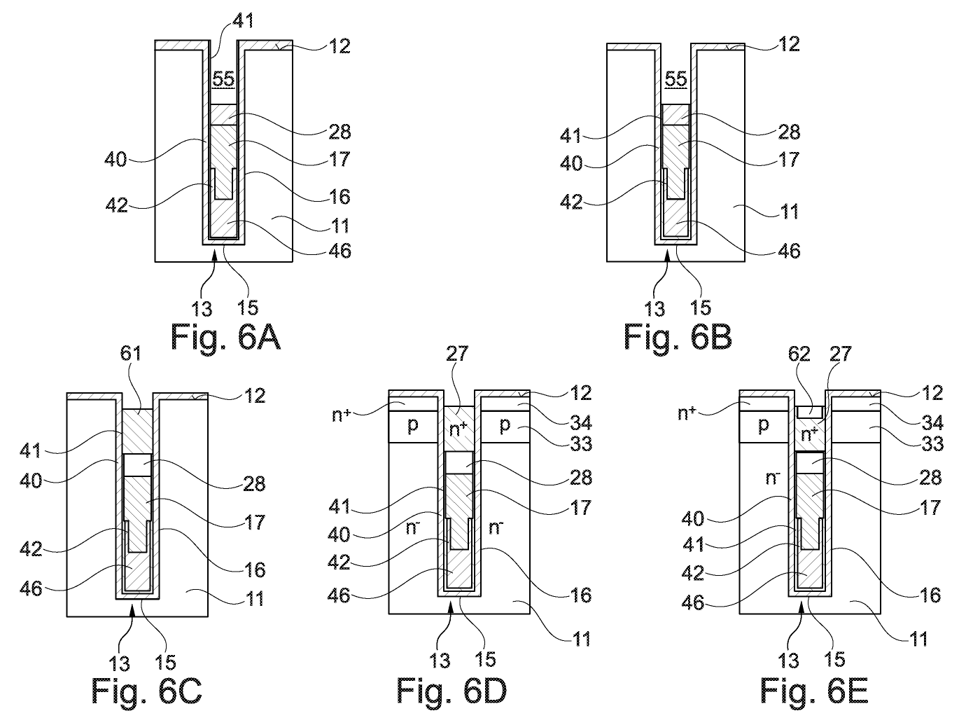

FIGS. 6A to 6E illustrate a method of forming the gate electrode 27 in the trench 13. The method described with reference to FIGS. 6A to 6E may be used after the method described with reference to FIGS. 5A to 5H and in place of the method described with reference to FIG. 5I.

FIG. 6A shows the device after forming the second intermediate dielectric 28 which covers the field plate 17 and after forming the gate dielectric 32 on the side face 16 of the trench 13 for the gate electrode. The method of fabricating the gate dielectric 32 by deposition only as described with reference to FIG. 5G is used. The first major surface 12 may be covered by the first sublayer 40 formed of oxide. To form the gate electrode 27, undoped or slightly doped polysilicon is inserted into the recess 55, as can be seen in FIG. 6B.

Referring to FIG. 6C, the body region 33 is then formed by implantation of dopants of the second conductivity type into the first major surface 12 of the semiconductor device 10 which has the first conductivity type. Referring to FIG. 6D, the source region 34 is formed in and/or on the body region 33 by implanting dopants of the first conductivity type into the first major surface 12. At the same time as the implantation process for the source region 34, or in an additional process, dopants of the first conductivity type are implanted into the undoped or slightly doped polysilicon material 61 located in the trench 13 so as to form a doped polysilicon member which is electrically conductive. This electrically conductive doped polysilicon member forms the gate electrode 27 in the trench 13. The first major surface 12 may be covered by the first sublayer 40 formed of an oxide during the implantation processes.

As shown in FIG. 6E, in some embodiments, a contact region 62 is formed in the upper surface of the gate electrode 27. For example, cobalt may be deposited and annealed into the upper surface so as to form a cobalt silicide region in the upper portion of the gate electrode 27. The region 62 extends to the upper surface of the gate electrode 27. An upper dielectric layer 31 may then be deposited which covers the first major surface 12 and the upper surface of the gate electrode 27.

The semiconductor devices 10 according to the embodiments described here have an improved efficiency due to the thicker bottom dielectric and optionally the stepped field plate and field dielectric. This improved efficiency is reflected in a reduced value of FOMoss, FOMoss denotes the output charge figure-of-merit, where FOMoss = RDS(on) x Qoss. represents a synthetic indicator of how well a transistor device behaves in conduction and switching.

Although the present disclosure is not so limited, the following numbered examples demonstrate one or more aspects of the disclosure.

1. A semiconductor device, comprising:

a semiconductor substrate comprising a first major surface;

at least one trench formed in the first major surface of the semiconductor substrate, at least one trench having a base and a side wall extending from the base to the first major surface;

a field plate located in the trench, wherein the field plate is electrically insulated from the semiconductor substrate by a dielectric structure,

wherein the dielectric structure comprises a bottom dielectric extending between the base of the trench and a lower surface of the field plate, wherein the bottom dielectric comprises a slightly doped polysilicon member.

2. The semiconductor device according to example 1, wherein the field plate is electrically conductive.

3. The semiconductor device according to example 1 or example 3, wherein the field plate is formed of highly doped polysilicon.

4. The semiconductor device according to any one of examples 1 to 3, further comprising a gate electrode located in a gate trench formed in the first major surface of the semiconductor substrate, wherein the gate trench is located laterally adjacent to the at least one trench.

5. The semiconductor device according to any one of examples 1 to 4, further comprising a gate electrode located in the trench, the gate electrode being arranged above the field plate, wherein the gate electrode is electrically insulated from the field plate and the semiconductor substrate by the dielectric structure.

6. The semiconductor device according to any one of examples 1 to 5, wherein the dielectric structure further comprises a dielectric liner layer arranged on the side wall of the trench and wherein the bottom dielectric comprises the dielectric layer on the side wall of the trench and the slightly doped polysilicon member and has a first thickness t1 and the dielectric liner layer on the side wall has a second thickness t2 at a position laterally adjacent a side face of the field plate; wherein the first thickness is measured in a first direction that is orthogonal to the base of the trench and the second thickness is measured in a second direction that is orthogonal to the side wall of the trench and the first thickness is greater than the second thickness.

7. The semiconductor device according to example 6, wherein the second thickness is measured in a second direction that is orthogonal to the first direction.

8. The semiconductor device according to example 6 or example 7, wherein the first thickness is at least two times greater than the second thickness or at least three times greater than the second thickness or at least five times greater than the second thickness.

9. The semiconductor device according to any one of examples 1 to 8, wherein the slightly doped polysilicon member is electrically insulating and the doped polysilicon of the field plate is electrically conductive.

10. The semiconductor device according to any one of examples 1 to 9, wherein the trench is tapered.

11. The semiconductor device according to any one of examples 1 to 10, wherein the trench has a width Wt at the first major surface, wherein 100 nm ≤ Wt ≤ 340 nm, and the base lies at a depth D from the first major surface, wherein 1 µm ≤ D 1.3 µm.)

12. The semiconductor device according to any one of examples 1 to 11, wherein the slightly doped polysilicon member has a height h, wherein 200 nm ≤ h ≤ 270 nm.

13. The semiconductor device according to any one of examples 1 to 12, wherein 250 nm ≤ t1 ≤ 300 nm and 70 nm ≤ t2 ≤ 100 nm.

14. The semiconductor device according to any one of examples 1 to 13, wherein the slightly doped polysilicon member has a dopant concentration of less than 10¹⁸cm⁻³ and the field plate is formed of doped polysilicon and has a dopant concentration of at least 10²⁰cm⁻³.

15. The semiconductor device according to any one of examples 1 to 14, wherein the bottom dielectric further comprises a dielectric liner layer that lines the base and side wall of the trench and a first intermediate dielectric layer that extends between an upper surface of the slightly doped polysilicon member and the lower surface of the field plate.

16. The semiconductor device according to any one of examples 1 to 15, wherein the dielectric liner layer and the first intermediate dielectric layer comprise an oxide.

17. The semiconductor device according to any one of examples 1 to 16, wherein the dielectric liner layer is formed by a section of the dielectric layer.

18. A semiconductor device, comprising:

a semiconductor substrate comprising a first major surface;

at least one trench formed in the first major surface of the semiconductor substrate, the at least one trench having a base and a side wall extending from the base to the first major surface;

a field plate and a gate electrode located in the trench, the gate electrode being arranged above the field plate, wherein the field plate and the gate electrode are electrically insulated from one another and the semiconductor substrate by a dielectric structure,

wherein the dielectric structure comprises a bottom dielectric extending between the base of the trench and a lower surface of the field plate and a dielectric layer arranged on the side wall of the trench,

wherein the bottom dielectric has a first thickness that is measured in a first direction that is orthogonal to the base of the trench, wherein the dielectric layer on the side wall has a second thickness measured in a second direction that is orthogonal to the side wall of the trench at a first position laterally adjacent a side face of the field plate and a third thickness measured in the second direction at a second position laterally adjacent the side face of the field plate; wherein the first thickness is greater than the second thickness and the third thickness is greater than the second thickness, wherein the first position is located at a greater distance from the base of the trench than the second position.

19. The semiconductor device according to example 18, wherein the second thickness is measured in a second direction that is orthogonal to the first direction.

20. The semiconductor device according to example 18 or example 19, wherein the first thickness is at least two times greater than the second thickness or at least three times greater than the second thickness or at least five times greater than the second thickness.

21. The semiconductor device according to any one of examples 18 to 20, wherein the trench is tapered.

22. The semiconductor device according to any one of examples 18 to 21, wherein the trench has a width Wt at the first major surface, wherein 100 nm ≤ Wt ≤ 340 nm, and the base lies at a depth D from the first major surface, wherein 1 µm ≤ D 1.3 µm.

23. The semiconductor device according to any one of examples 18 to 22, wherein 250 nm ≤ t1 ≤ 300 nm and 70 nm ≤ t2 ≤ 100 nm.

24. The semiconductor device according to any one of examples 18 to 23, wherein the field plate comprises an upper portion with a width W1 and a lower portion with a width W2, wherein W1 > W2.

25. The semiconductor device according to any one of examples 18 to 24, wherein 70 nm ≤ W1 ≤ 90 nm and 60 nm ≤ W2 ≤ 80 nm.

26. The semiconductor device according to any one of examples 18 to 25, wherein the upper portion of the field plate has a height h1 and the lower portion of the field plate has a height h2.

27. The semiconductor device according to example 26, wherein 50 nm ≤ h1 ≤ 80 nm and 50 nm ≤ h2 ≤ 80 nm.

28. The semiconductor device according to any one of examples 18 to 27, wherein the field plate comprises least one step in its outer surface between the lower portion and the upper portion.

29. The semiconductor device according to any one of examples 18 to 28, wherein the dielectric layer has the second thickness t2 at a location laterally adjacent the lower portion of the field plate and a third thickness t3 at a location laterally adjacent the upper portion of the field plate, wherein the third thickness t3 is smaller than the first thickness t1.

30. The semiconductor device according to example 29, wherein 50 nm ≤ t3 ≤ 80 nm.

31. The semiconductor device according to any one of examples 18 to 30, further comprising a second intermediate dielectric layer that extends between an upper surface of the field plate and a lower surface of the gate electrode.

32. The semiconductor device according to any one of examples 18 to 31, wherein the trench has an elongate stripe-like form.

33. The semiconductor device according to any one of examples 1 to 32, wherein the dielectric layer lines the side wall and base of the trench and comprises a first oxide sublayer on the side wall and base, a nitride sub layer on the first oxide sublayer and a second oxide sublayer on the nitride sublayer.

34. The semiconductor device according to example 33, wherein the nitride sublayer is in contact with the upper portion of the field plate and in contact with the first oxide sublayer in a position laterally adjacent the lower portion of the field plate.

35. The semiconductor device according to example 33 or example 34, wherein the nitride layer is further in contact with a second intermediate layer that extends between an upper surface of the field plate and a lower surface of the gate electrode.

36. The semiconductor device according to any one of examples 18 to 35, wherein the semiconductor device comprises a plurality of transistor cells, and a plurality of trenches, each transistor cell comprising one of the plurality of trenches and a mesa, wherein the semiconductor substrate comprises a first conductivity type and provides the drift region, a body region of a second conductivity type that opposes the first conductivity type is formed in the mesa, a source region of the second conductivity type is formed on and/or in the body region and a drain region of the first conductivity type is formed at a second major surface of the semiconductor substrate that opposes the first major surface.

37. The semiconductor device according to any one of examples 1 to 36, wherein the semiconductor substrate comprises silicon.

38. The semiconductor device according to example 37, wherein the semiconductor substrate is formed of monocrystalline silicon or an epitaxial silicon layer.

39. A method for forming a dielectric structure in a trench, the method comprising:

forming a trench in a first major surface of a semiconductor substrate, the trench comprising a base and a side wall that extends from the base to the first major surface,

forming a first dielectric layer on the side wall and base of the trench;

forming a bottom dielectric on the first dielectric on the base of the trench, the bottom dielectric comprising slightly doped polysilicon;

forming a first intermediate dielectric layer on the slightly doped polysilicon;

forming a field plate on the first intermediate dielectric layer;

forming a second intermediate dielectric layer on the field plate;

forming a gate electrode on the second intermediate dielectric layer.

40. A method for forming a dielectric structure in a trench, the method comprising:

forming a trench in a first major surface of a semiconductor substrate, the trench comprising a base and a side wall that extends from the base to the first major surface,

forming a first dielectric layer on the side wall of the trench;

forming a bottom dielectric on the base of the trench;

forming a first intermediate dielectric layer on the undoped polysilicon;

forming a field plate on the first intermediate dielectric layer,

wherein the field plate comprises an upper portion with a width W1 and a lower portion with a width W2, wherein W1 > W2;

forming a second intermediate dielectric layer on the field plate;

forming a gate electrode on the second intermediate dielectric layer,

wherein the bottom dielectric has a first thickness that is measured in a first direction that is orthogonal to the base of the trench and the first dielectric layer has a second thickness that is measured in a second direction that is orthogonal to the side wall of the trench, wherein the first thickness is greater than the second thickness,

wherein the second thickness is measured in a second direction that is orthogonal to the first direction.

41. The method according to example 39 or example 40, wherein 70 nm ≤ W1 ≤ 90 nm and 60 nm ≤ W2 ≤ 80 nm.

42. A method according to any one of examples 39 to 41, wherein the upper portion of the field plate has a height H1 and the lower portion of the field plate has a height h2.

43. A method according to claim 42, wherein 50 nm ≤ h1 ≤ 80 nm and 50 nm ≤ h2 ≤ 80 nm.

44. A method according to any one of examples 39 to 43, wherein the field plate comprises least one step in its outer surface between the lower portion and the upper portion.

45. A method according to any one of examples 39 to 44, wherein the dielectric layer has the second thickness t2 at a location laterally adjacent the lower portion of the field plate and a third thickness t3 at a location laterally adjacent the upper portion of the field plate, wherein the third thickness t3 is smaller than the first thickness t1.

46. A method according to claim 45, wherein 50 nm ≤ t3 ≤ 80 nm.

47. A method according to any one of examples 39 to 46, further comprising a second intermediate dielectric layer that extends between an upper surface of the field plate and a lower surface of the gate electrode.

48. A method according to any one of examples 39 to 47, wherein the trench has an elongate stripe-like form.

49. The method according to any one of examples 40 to 48, wherein the bottom dielectric has a first thickness and the first dielectric layer has a second thickness, wherein the first thickness is greater than the second thickness.

50. The method according to example 40 or example 49, wherein the first thickness is at least two times greater than the second thickness or at least three times greater than the second thickness or at least five times the thickness.

51. A method according to any one of examples 39 to 50, wherein the slightly doped polysilicon member is electrically insulating and the doped polysilicon of the field plate is electrically conductive.

52. The method according to any one of examples 39 to 51, wherein the slightly doped polysilicon has a dopant concentration of less than 10¹⁸cm⁻³ and the field plate is formed of doped polysilicon and has a dopant concentration of at least 10²⁰cm⁻³.

53. The method according to any one of examples 39 to 52, wherein the forming the bottom dielectric comprises:

forming the first dielectric layer on the base and the side wall of the trench, wherein the dielectric layer surrounds a first recess, and

inserting slightly doped polysilicon material into the first recess to form a slightly doped polysilicon member, and

forming the first intermediate dielectric layer on the slightly doped polysilicon member.

54. The method according to example 53, wherein the forming the first intermediate dielectric layer comprises:

forming a second dielectric layer on the side wall of the trench and on the slightly doped polysilicon material to form the first intermediate dielectric layer, wherein the second dielectric layer bounds a second recess;

inserting conductive material into the second recess to form the field plate.

55. The method according to any one of examples 39 to 54, wherein the forming the gate electrode comprises:

removing a portion of the dielectric layer from the side wall to form a gate dielectric on the side wall of the trench;

inserting conductive material into the trench and forming the gate electrode.

56. The method according to example 55, wherein the forming the gate electrode further comprises:

removing an upper portion of the gate electrode such that an upper surface of the gate electrode lies in a plane below the first major surface, and

forming a dielectric layer on the gate electrode and first major surface.

57. The method according to any one of examples 39 to 56, wherein the forming the field plate comprises:

after forming the first intermediate dielectric layer:

inserting sacrificial material into the trench so as to cover the second dielectric layer on the side wall in the lower portion of the trench and leave the dielectric layer exposed on the side wall in the upper part of the trench;

removing a portion of the second dielectric layer exposed on the side walls<,

removing the sacrificial material, and

inserting conductive material into the trench to form the field plate with an upper portion with a width W1 and a lower portion with a width W2, wherein W1 > W2.

58. The method according to any one of examples 39 to 57, wherein the conductive material fills the trench and the method comprises removing upper portion of the conductive material.

59. The method according to example 58, wherein the sacrificial material is slightly doped polysilicon.

60. The method according to any one of examples 39 to 59, wherein the forming the first dielectric layer comprises:

forming a first oxide sublayer on the base and side wall of the trench,

forming a nitride sublayer on the first oxide sublayer;

forming a second oxide layer on the nitride layer.

61. The method according to any one of examples 39 to 60, wherein the forming the first dielectric layer comprises:

forming a first oxide sublayer on the base and side wall of the trench,

forming a nitride sublayer on the first oxide sublayer;

forming a second oxide layer on the nitride layer, and then the method comprises:

inserting slightly doped polysilicon into the first recess, and

oxidizing the slightly doped polysilicon to form a bottom dielectric.

62. The method according to example 61, further comprising: after forming the bottom dielectric,

inserting sacrificial material into trench,

selectively removing exposed portions of the second oxide sublayer and exposing the nitride sublayer,

removing the sacrificial material,

inserting conductive material into the trench and forming the field plate, the field plate having a step in its outer surface.

63. The method according to example 62, further comprising: after removing the second oxide sublayer, removing the nitride sublayer, depositing a third oxide layer on the first oxide sublayer to the form the gate dielectric and then inserting the conductive material into the trench and forming the gate electrode.

64. The method according to example 62, further comprising:

after removing the second oxide sublayer,

removing the exposed nitride sublayer and then the exposed first oxide sublayer from side wall of the trench and exposing the side wall of the trench;

forming the second intermediate dielectric layer on the field plate, forming the gate dielectric on the exposed side wall of the trench and forming the gate electrode in the trench.

65. The method according to example 64, wherein the forming the gate dielectric comprises thermally oxidising the exposed side wall of the trench.

66. The method according to example 62, further comprising:

inserting dielectric material into the trench to form the second intermediate dielectric layer,

removing exposed portion of the nitride sublayer, at least a portion of the first dielectric sublayer remaining on the side wall of the trench and forming the gate dielectric;

inserting conductive material into the trench and forming the gate electrode.

67. The method according to any one of examples 39 to 66, further comprising:

implanting dopants of a second conductivity type into the first major surface of the semiconductor substrate and forming a body region;

implanting dopants of a first conductivity type into the first major surface of the semiconductor substrate and into the body region to form a source region

68. The method according to any one of examples 39 to 67, wherein the forming the gate electrode comprises:

inserting slightly doped polysilicon into the trench;

implanting dopants of a second conductivity type into the first major surface of the semiconductor substrate and forming a body region;

implanting dopants of a first conductivity type into the first major surface of the semiconductor substrate and into the slightly doped polysilicon in the trench to form a source region and a conductive gate electrode, respectively,

forming a CoSi2 contact in a region of the gate electrode.

Spatially relative terms such as "under", "below", "lower", "over", "upper" and the like are used for ease of description to explain the positioning of one element relative to a second element. These terms are intended to encompass different orientations of the device in addition to different orientations than those depicted in the figures. Further, terms such as "first", "second", and the like, are also used to describe various elements, regions, sections, etc. and are also not intended to be limiting. Like terms refer to like elements throughout the description.

As used herein, the terms "having", "containing", "including", "comprising" and the like are open ended terms that indicate the presence of stated elements or features, but do not preclude additional elements or features. The articles "a", "an" and "the" are intended to include the plural as well as the singular, unless the context clearly indicates otherwise. It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate comprising a first major surface;
at least one trench formed in the first major surface of the semiconductor substrate, the at least one trench having a base and a side wall extending from the base to the first major surface; and
a field plate located in the trench and electrically insulated from the semiconductor substrate by a dielectric structure,
wherein the dielectric structure comprises a bottom dielectric extending between the base of the trench and a lower surface of the field plate,
wherein the bottom dielectric comprises a slightly doped polysilicon member.

2. The semiconductor device of claim 1, wherein the dielectric structure further comprises a dielectric layer arranged on the side wall of the trench, wherein the bottom dielectric comprises the dielectric layer on the side wall of the trench and the slightly doped polysilicon member, and has a first thickness between the base of the trench and the lower surface of the field plate, wherein the dielectric layer on the side wall has a second thickness at a position laterally adjacent a side face of the field plate, wherein the first thickness is measured in a first direction that is orthogonal to the base of the trench and the second thickness is measured in a second direction that is orthogonal to the side wall of the trench, and wherein the first thickness is greater than the second thickness.

3. The semiconductor device of claim 2, wherein the first thickness is at least two times greater than the second thickness.

4. The semiconductor device of claim 1, wherein the slightly doped polysilicon member has a dopant concentration of less than 10¹⁸cm⁻³ and wherein the field plate is formed of doped polysilicon and has a dopant concentration of at least 10²⁰cm⁻³.

5. The semiconductor device of claim 1, wherein the bottom dielectric further comprises a dielectric layer that lines the base and the side wall of the trench and a first intermediate dielectric layer that extends between an upper surface of the slightly doped polysilicon member and the lower surface of the electrode.

6. The semiconductor device of claim 1, further comprising a gate electrode in the trench above the field plate.

7. The semiconductor device of claim 1, wherein the bottom dielectric has a first thickness that is measured in a first direction that is orthogonal to the base of the trench, wherein the dielectric layer on the side wall has a second thickness measured in a second direction that is orthogonal to the side wall of the trench and located at a first position laterally adjacent a side face of the field plate and a third thickness measured in the second direction and located at a second position laterally adjacent the side face of the field plate, wherein the first thickness is greater than the second thickness and the third thickness is greater than the second thickness, and wherein the first position is located at a greater distance from the base of the trench than the second position.

8. The semiconductor device of claim 7, wherein the first thickness is at least two times greater than the second thickness.

9. The semiconductor device of claim 1, wherein the field plate comprises an upper portion with a width W1 and a lower portion with a width W2, and wherein W1 > W2.

10. The semiconductor device of claim 1, wherein the dielectric layer lines the side wall and the base of the trench, and wherein the dielectric layer comprises a first oxide sublayer on the side wall and the base, a nitride sublayer on the first oxide sublayer and a second oxide sublayer on the nitride sublayer.

11. The semiconductor device of claim 10, wherein the nitride sublayer is in contact with an upper portion of the field plate and in contact with the first oxide sublayer in a position laterally adjacent a lower portion of the field plate.

12. The semiconductor device of claim 10, wherein the nitride layer is in contact with a second intermediate layer that extends between an upper surface of the field plate and a lower surface of the gate electrode.

13. A method for forming a dielectric structure in a trench, the method comprising:
forming a trench in a first major surface of a semiconductor substrate, the trench comprising a base and a side wall that extends from the base to the first major surface;
forming a first dielectric layer on the side wall and the base of the trench;
forming a bottom dielectric on the first dielectric layer on the base of the trench, the bottom dielectric comprising slightly doped polysilicon;
forming a first intermediate dielectric layer on the slightly doped polysilicon;
forming a field plate on the first intermediate dielectric layer;
forming a second intermediate dielectric layer on the field plate;
forming a gate electrode on the second intermediate dielectric layer.

14. The method of claim 13, wherein the bottom dielectric has a first thickness that is measured in a first direction that is orthogonal to the base of the trench, wherein the first dielectric layer has a second thickness that is measured in a second direction that is orthogonal to the side wall of the trench, and wherein the first thickness is greater than the second thickness.

15. The method of claim 13, wherein the bottom dielectric has a first thickness and the first dielectric layer has a second thickness, and wherein the first thickness is greater than the second thickness.

16. The method of claim 15, wherein the first thickness is at least two times greater than the second thickness.

17. The method of claim 13, wherein the slightly doped polysilicon has a dopant concentration of less than 10¹⁸cm⁻³ and wherein the field plate is formed of doped polysilicon and has a dopant concentration of at least 110²⁰cm⁻³.

18. The method of claim 13, wherein forming the bottom dielectric comprises:
forming the first dielectric layer on the base and the side wall of the trench, wherein the dielectric layer surrounds a first recess;
inserting slightly doped polysilicon material into the first recess to form a slightly doped polysilicon member; and
forming the first intermediate dielectric layer on the slightly doped polysilicon member.

19. The method of claim 18, wherein forming the first intermediate dielectric layer comprises:
forming a second dielectric layer on the side wall of the trench and on the slightly doped polysilicon member to form the first intermediate dielectric layer, wherein the second dielectric layer bounds a second recess; and
inserting conductive material into the second recess to form the field plate.

20. The method of claim 13, wherein forming the gate electrode comprises:
removing a portion of the dielectric layer from the side wall to form a gate dielectric on the side wall of the trench; and
inserting conductive material into the trench.
